(19) United States
(12) Patent Application Publication
(10) Pub. No.: US 2013/0206067 A1
(43) Pub. Date: Aug. 15, 2013

(54) FILM DEPOSITION APPARATUS

(71) Applicant: Tokyo Electron Limited, (US)

(72) Inventors: Hitoshi Kato, Iwate (JP); Shigehiro Miura, Iwate (JP)

(73) Assignee: Tokyo Electron Limited, Tokyo (JP)

(21) Appl. No.: 13/761,257

(22) Filed: Feb. 7, 2013

(30) Foreign Application Priority Data
Feb. 9, 2012 (JP) 2012-026330

(51) Int. Cl. H01L 21/02

(52) U.S. Cl. CPC H01L 21/02104
USPC 118/719

(57) ABSTRACT

A film deposition apparatus includes a first plasma processing unit which performs a plasma process to a substrate at a second process area wherein the first plasma processing unit includes a first surrounding portion for forming a plasma generation space where plasma is generated, provided with a discharge port at a lower end portion, a second process gas supplying unit which supplies a second process gas to a plasma generation space, an activating unit which activates the second process gas in the plasma generation space, and a second surrounding portion provided below the first surrounding portion for forming a guide space which extends from a center portion side to an outer periphery portion side of the turntable so that the plasma discharged from the discharge port is guided to the surface of the turntable.

### CROSS-REFERENCE TO RELATED APPLICATION

The present application is based on Japanese Priority Application No. 2012-026330 filed on Feb. 9, 2012, the entire contents of which are hereby incorporated by reference.

### BACKGROUND OF THE INVENTION

1. Field of the Invention

The present invention relates to a film deposition apparatus in which process gases which react with each other are alternately provided to form a reaction product on a surface of a substrate and a plasma process is performed for the substrate.

2. Description of the Related Art

As one of methods of depositing a thin film such as a silicon nitride film (SiN) or the like on a substrate such as a semiconductor wafer (hereinafter simply referred to as a “wafer”), Atomic Layer Deposition (ALD) is known by which plural kinds of process gases (reaction gases) which are react with each other are alternately supplied onto a surface of the wafer to form a stacked structure of a reaction product. A film deposition apparatus used for ALD includes a structure in which a turntable for rotating plural wafers aligned in a circumferential direction is provided in a vacuum chamber and gas supplying nozzles are further provided to face the turntable, as disclosed in Patent Document 1. In this film deposition apparatus, separation areas to which a separation gas is supplied are provided between process areas to which the process gases are supplied in order to prevent mixing of different kinds of process gases.

In such an apparatus, as disclosed in Patent Document 2, for example, a structure is known in which a plasma area where a surface treatment of a reaction product or activation of a process gas, for example, is performed using plasma is provided in addition to process areas and separation areas in a circumferential direction of a turntable. However, in order to make the size of the apparatus small, it is difficult to provide such a plasma area. In other words, if the plasma area is provided, the apparatus becomes larger.

### PATENT DOCUMENT

[Patent Document 1] Japanese Laid-open Patent Publication No. 2010-239102
[Patent Document 2] Japanese Laid-open Patent Publication No. 2011-40574

### SUMMARY OF THE INVENTION

The present invention is made in light of the above problems, and provides a film deposition apparatus in which process gases which react with each other are alternately provided to form a reaction product on a surface of a substrate and a plasma process is performed for the substrate, capable of structuring a small size vacuum chamber while preventing mixture of process gases in the vacuum chamber.

According to an embodiment, there is provided a film deposition apparatus in which a thin film is formed on a substrate by performing a cycle for plural times in which plural kinds of process gases which react with each other are supplied onto the substrate so that a reaction product is stacked on the substrate in a vacuum chamber, including a turntable placed in the vacuum chamber and provided with a substrate mounting area on which a substrate is to be mounted at a surface for rotating the substrate mounting area; a first process gas supplying unit which supplies a first process gas to a first process area; a first plasma processing unit which performs a plasma process to the substrate at a second process area; a separation gas supplying unit which supplies a separation gas to a separation area between the first process area and the second process area for separating atmospheres of the first process area and the second process area; an evacuation port which evacuates the atmosphere of the vacuum chamber. The first plasma processing unit includes a first surrounding portion for forming a plasma generation space where plasma is generated, provided with a discharge port at a lower end portion, a second process gas supplying unit which supplies a second process gas to a plasma generation space, an activating unit which activates the second process gas in the plasma generation space, and a second surrounding portion provided below the first surrounding portion for forming a guide space which extends from a center portion side to an outer periphery portion side of the turntable so that the plasma discharged from the discharge port is guided to the surface of the turntable.

Note that also arbitrary combinations of the above-described constituents, and any exchanges of expressions in the present invention, made among methods, devices and so forth, are valid as embodiments of the present invention.

### BRIEF DESCRIPTION OF THE DRAWINGS

Other objects, features and advantages of the present invention will become more apparent from the following detailed description when read in conjunction with the accompanying drawings.

FIG. 1 is a cross-sectional view showing an example of film deposition apparatus of an embodiment;

FIG. 2 is a lateral cross-sectional plan view of the film deposition apparatus of the embodiment;

FIG. 3 is a lateral cross-sectional plan view of the film deposition apparatus of the embodiment;

FIG. 4 is an enlarged cross-sectional view showing a plasma generation chamber of the film deposition apparatus of the embodiment;

FIG. 5 is a perspective view showing the plasma generation chamber of the embodiment;

FIG. 6 is a perspective view showing a part of the plasma generation chamber of the embodiment;

FIG. 7 is a perspective view showing a part of the plasma generation chamber of the embodiment;

FIG. 8 is an exploded perspective view showing the plasma generation chamber of the embodiment;

FIG. 9 is a perspective view showing a part of a fin provided in the plasma generation chamber of the embodiment;

FIG. 10 is a cross-sectional view showing the fin of the embodiment;

FIG. 11 is a cross-sectional view showing the fin of the embodiment;

FIG. 12 is a perspective view showing a nozzle cover provided at a first process gas nozzle;

FIG. 13 is a cross-sectional view showing the nozzle cover of the embodiment;

FIG. 14 is a cross-sectional view showing a second plasma generation unit of the film deposition apparatus of the embodiment;

FIG. 15 is an exploded perspective view showing the second plasma generation unit of the embodiment;

FIG. 16 is a perspective view showing a housing provided at the second plasma generation unit of the embodiment;

FIG. 17 is a plan view showing the second plasma generation unit of the embodiment;

FIG. 18 is a perspective view showing a part of a Faraday shield provided at the second plasma generation unit of the embodiment;

FIG. 19 is an exploded perspective view showing a side ring provided at the film deposition apparatus of the embodiment;

FIG. 20A and FIG. 20B are cross-sectional views of the film deposition apparatus of the embodiment taken along a line extending in a circumferential direction;

FIG. 21 is a schematic view showing a gas flow in the film deposition apparatus of the embodiment;

FIG. 22 is an exploded perspective view showing another example of the film deposition apparatus of the embodiment;

FIG. 23 is a cross-sectional view showing another example of the film deposition apparatus of the embodiment;

FIG. 24 is a perspective view showing another example of the film deposition apparatus of the embodiment;

FIG. 25 is a lateral cross-sectional plan view showing another example of the film deposition apparatus of the embodiment;

FIG. 26 is a perspective view showing another example of the film deposition apparatus of the embodiment;

FIG. 27 is a perspective view showing another example of the film deposition apparatus of the embodiment;

FIG. 28 is a cross-sectional view showing another example of the film deposition apparatus of the embodiment;

FIG. 29 is a cross-sectional view showing another example of the film deposition apparatus of the embodiment;

FIG. 30 is a view showing path lines in the vacuum chamber obtained in an example;

FIG. 31 is a view showing path lines in the vacuum chamber obtained in an example;

FIG. 32 is a view showing path lines in the vacuum chamber obtained in an example;

FIG. 33 is a view showing path lines in the vacuum chamber obtained in an example;

FIG. 34 is a view showing path lines in the vacuum chamber obtained in an example;

FIG. 35 is a view showing path lines in the vacuum chamber obtained in an example;

FIG. 36 is a view showing path lines in the vacuum chamber obtained in an example;

FIG. 37 is a view showing path lines in the vacuum chamber obtained in an example;

FIG. 38 is a view showing path lines in the vacuum chamber obtained in an example; and

FIG. 39 is a view showing path lines in the vacuum chamber obtained in an example.

### DETAILED DESCRIPTION OF THE PREFERRED EMBODIMENTS

The invention will be described herein with reference to illustrative embodiments. Those skilled in the art will recognize that many alternative embodiments can be accomplished using the teachings of the present invention and that the invention is not limited to the embodiments illustrated for explanatory purposes.

It is to be noted that, in the explanation of the drawings, the same components are given the same reference numerals, and explanations are not repeated. Further, drawings are not intended to show relative ratios of a component or components.

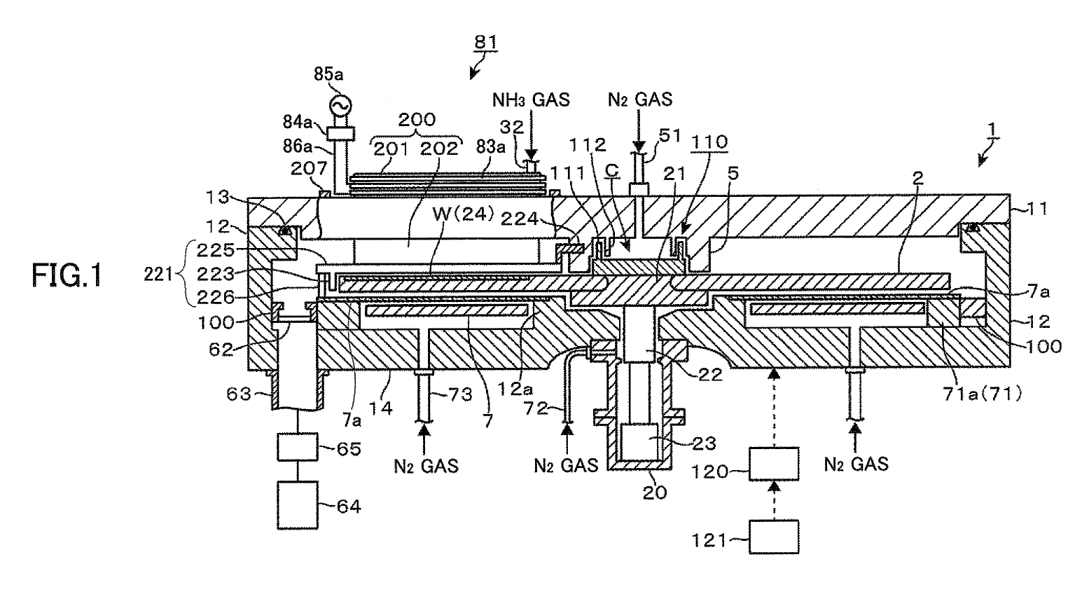

An example of a film deposition apparatus is explained with reference to FIG. 1 to FIG. 19. As shown in FIG. 1 to FIG. 3, the film deposition apparatus includes a vacuum chamber 1 having a substantially flat circular shape, and a turntable 2 provided in the vacuum chamber 1 with a rotation center at the center of the vacuum chamber 1 for rotating wafers W.

As will be explained later in detail, the film deposition apparatus is configured to perform an adsorption process of adsorbing Si containing gas onto the wafer W, a plasma nitriding process of nitriding the Si containing gas adsorbed on the wafer W to form a silicon nitride film and a surface treatment process of treating the silicon nitride film formed on the wafer W every rotation of the turntable 2. Further, the film deposition apparatus is configured to have the size of the vacuum chamber 1 as small as possible in a plan view when providing components such as nozzles or the like for performing these processes while preventing mixing of process gases used in the adsorption process and in the nitriding process in the vacuum chamber 1. Next, each component of the film deposition apparatus is explained in detail.

The vacuum chamber 1 includes a chamber body 12 and a ceiling plate (ceiling portion) 11 which is detachably attached to the chamber body 12. The diameter (the inner diameter) of the vacuum chamber 1 in a plan view is about 1100 mm, for example. A separation gas supplying pipe 51 for supplying nitrogen (N₂) gas as a separation gas in order to suppress mixing of different kinds of process gases at a center area C in the vacuum chamber 1 is connected at a center portion at an upper surface of the ceiling plate 11. Further, a ring-shaped sealing member 13 such as an O-ring or the like is provided at an upper outer periphery portion of the chamber body 12.

The vacuum chamber 1 includes a cylindrical shaped core unit 21, a rotary shaft 22 connected to a lower surface of the core unit 21 and extended in the vertical direction, a driving unit 23 which rotates the rotary shaft 22 around a vertical axis, and a case body 20 which houses the rotary shaft 22 and the driving unit 23.

The turntable 2 is fixed to the core unit 21 at it center. The turntable 2 is configured to be rotatable around the vertical axis (in this embodiment, a clockwise direction) by the rotary shaft 22. The diameter of the turntable 2 is, for example, 1000 mm. The case body 20 has a flange portion at an upper surface which is attached to a lower surface of the bottom portion 14 of the vacuum chamber 1 in an air-tight manner. A purge gas supplying pipe 72 is connected to the case body 20 for supplying nitrogen gas as a purge gas below the turntable 2. The bottom portion 14 of the vacuum chamber 1 at an outer periphery side of the core unit 21 is formed in a ring shape to extend closer to the turntable 2 from a lower side to form a protruded portion 12a.

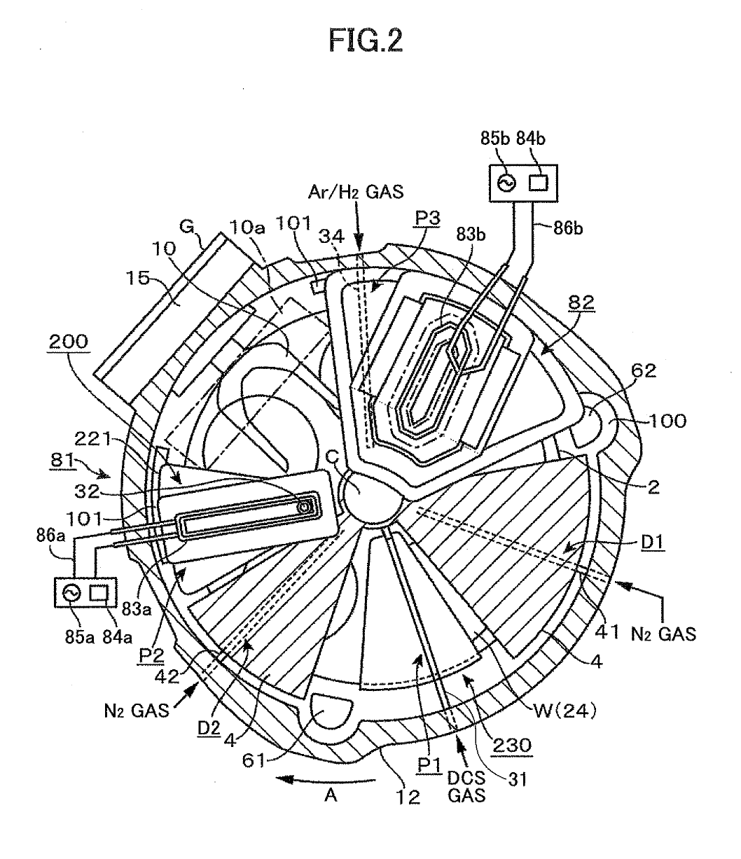

As shown in FIG. 2 to FIG. 4, the turntable 2 is provided with plural circular concave portions 24 as substrate mounting areas at its surface portion for mounting the wafers W, respectively. The concave portions 24 are provided at plural, five, for example, positions along a rotational direction (circumferential direction) of the turntable 2. Each of the concave portions 24 is formed to have a diameter and a depth such that the surface of the wafer W, which is mounted on the concave portion 24, and the surface of the turntable 2 (where the concave portions 24 are not formed) become almost the same height. The diameter of the wafer W may be, for example, 300 mm. Each of the concave portions 24 is provided with through holes (not shown in the drawings) through which three lift pins, for example, for supporting a back surface of the respective wafer W and lifting the wafer W penetrate.

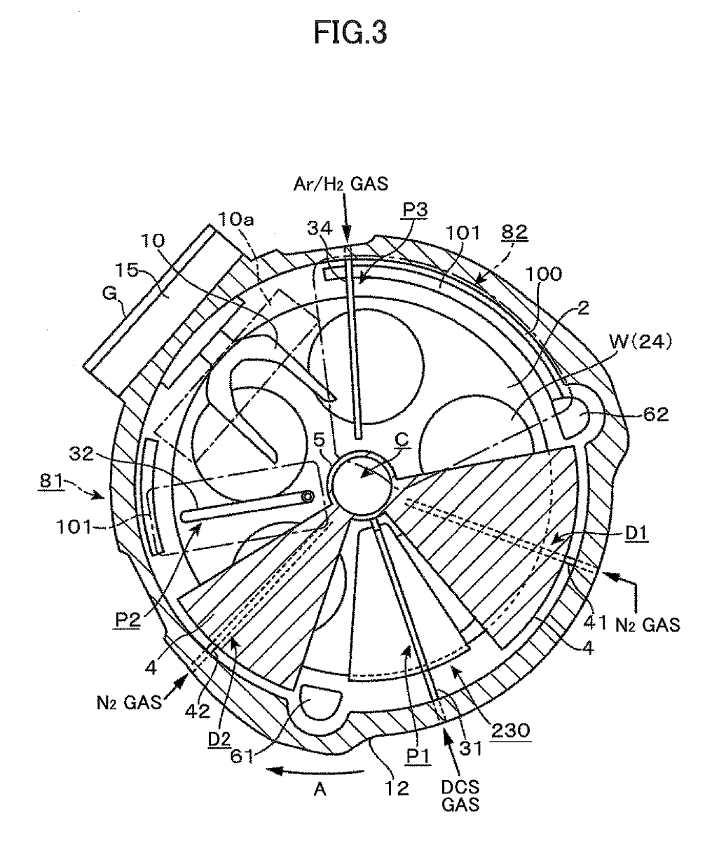

As shown in FIG. 2 and FIG. 3, four gas nozzles, a first process gas nozzle 31, a third process gas nozzle 34 and separation gas nozzles 41 and 42, made of quartz, for example, are radially placed in the circumferential direction (the rotational direction) of the turntable 2 with spaces between each other at positions facing areas where the concave portions 24 of the turntable 2 pass in the vacuum chamber 1, respectively. Each of the gas nozzles 31, 34, 41 and 42 are fixed to an outer peripheral wall of the vacuum chamber 1 toward the center area C in a parallel relationship with and facing the wafers W. In this embodiment, the third process gas nozzle 34, the separation gas nozzle 41, the first process gas nozzle 31 and the separation gas nozzle 42 are aligned in this order in a clockwise direction (the rotational direction A of the turntable 2) from a transfer port 15, which will be explained later.

In this embodiment, a second process gas nozzle 32 is further provided at an upstream side of the transfer port 15 in the rotational direction of the turntable 2 (between the separation gas nozzle 42 and the third process gas nozzle 34) above the ceiling plate 11. Similar to the gas nozzles 31, 34, 41 and 42, the second process gas nozzle 32 is made of quartz or the like. The structure of the second process gas nozzle 32 which is positioned above the ceiling plate 11 will be explained later in detail.

Here, in FIG. 2 and FIG. 3, the ceiling plate 11 is not shown, and further in FIG. 3, the second process gas nozzle 32 is only schematically shown. FIG. 3 shows a state in which a first plasma generation unit 81, a plasma generation chamber 200, a second plasma generation unit 82 and a housing 90 are removed. On the other hand, FIG. 2 shows a state in which the first plasma generation unit 81, the plasma generation chamber 200, the second plasma generation unit 82 and the housing 90, which will be explained later, are attached.

The first process gas nozzle 31 is an example of a process gas supplying unit. The second process gas nozzle 32 is an example of a second process gas supplying unit (a plasma generating gas supplying unit). The third process gas nozzle 34 is an example of a third process gas supplying unit (an additional plasma generating gas supplying unit). The separation gas nozzles 41 and 42 are an example of separation gas supplying units, respectively.

Each of the gas nozzles 31, 32, 34, 41 and 42 is connected to a following respective gas supplying source (not shown in the drawings) via a respective flow controller valve. The first process gas nozzle 31 is connected to a supplying source of a first process gas which is a silicon (Si) containing gas such as Dichlorosilane (DCS) gas or the like, for example. The second process gas nozzle 32 is connected to a supplying source of a second process gas which is a mixed gas of ammonia (NH₃) gas and argon (Ar) gas, for example. The third process gas nozzle 34 is connected to a supplying source of a third process gas (a surface treatment gas) which is a mixed gas of argon gas and hydrogen (H₂) gas, for example. The separation gas nozzles 41 and 42 are respectively connected to supplying sources of separation gases, which is a nitrogen gas, for example. The gas supplied from the second process gas nozzle 32 is exemplified as ammonia gas in order for simplifying the explanation in the following. However, alternatively, a gas containing nitrogen element (N) such as nitrogen (N₂) gas, for example, may be used instead of ammonia gas.

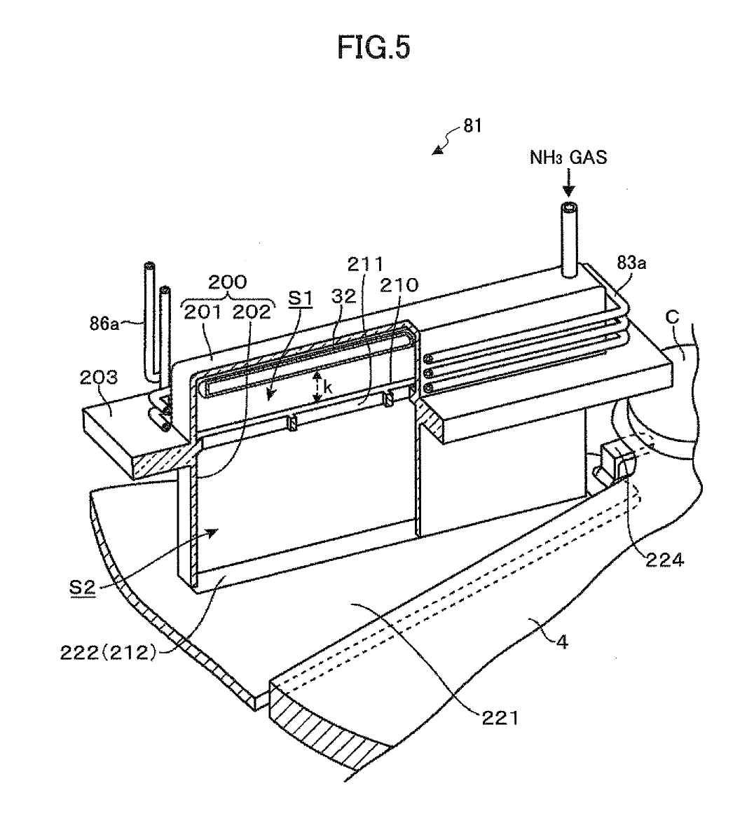

Plural gas discharge holes 33 for discharging the respective gas is provided at a lower surface side of each of the gas nozzles 31, 32, 34, 41 and 42 along a radial direction of the turntable 2 with a predetermined interval, for example. Each of the gas nozzles 31, 34, 41 and 42 is positioned such that the lower end of the respective gas nozzle 31, 34, 41 or 42 and the upper surface of the turntable 2 becomes about 1 to 5 mm, for example. In FIG. 5, the gas discharge holes 33 of the second process gas nozzle 32 are not shown.

A lower area of the first process gas nozzle 31 is a first process areas P1 for having the Si containing gas adsorbed onto the wafer W, a lower area of the second process gas nozzle 32 inside the vacuum chamber 1 is a second process areas P2 for having the Si containing gas adsorbed on the wafer W reacting with ammonia gas (specifically, ammonia gas plasma). A lower area of the third process gas nozzle 34 is a third process areas P3 for performing a surface treatment of a reaction product formed on the wafer W after passing through the process areas P1 and P2. The separation gas nozzles 41 and 42 are provided for forming a first separation area D1 and a second separation area D2 which divide the first process area P1 and the third process area P3, and the first process area P1 and the second process area P2, respectively.

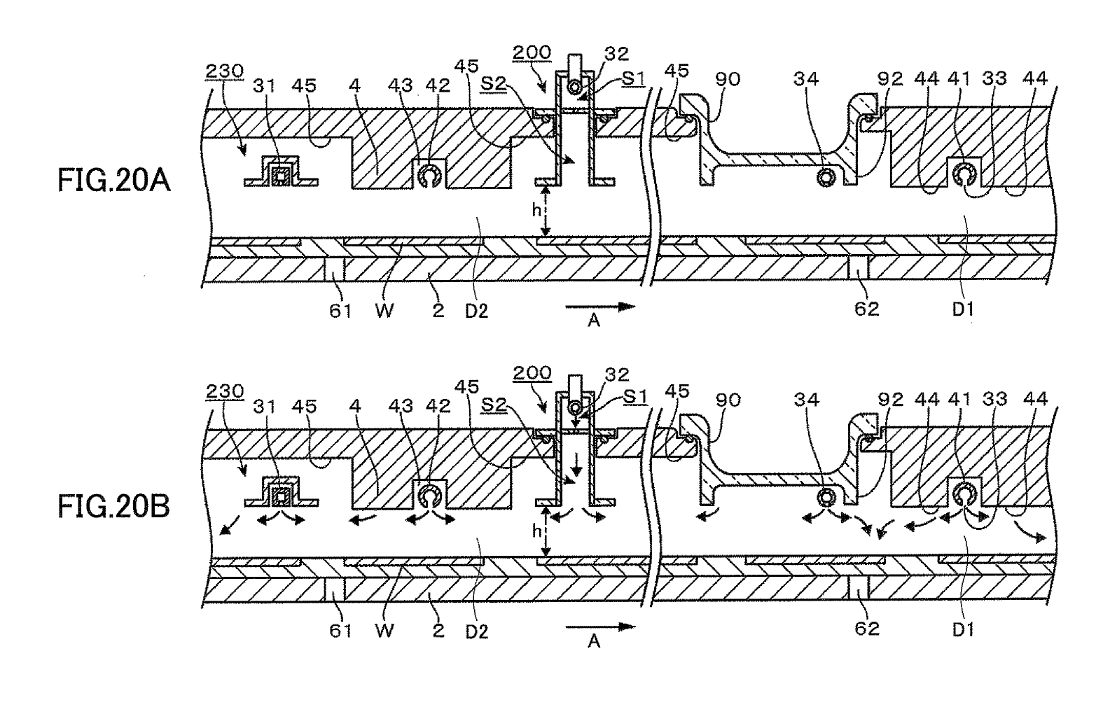

As shown in FIG. 2 and FIG. 3, protruding portions 4 each having substantially a sector top view shape are provided to the ceiling plate 11 of the vacuum chamber 1 in the first separation area D1 and in the second separation area D2. The separation gas nozzle 41 is housed in a groove portion provided at the protruding portion 4 (see FIG. 20A, FIG. 20B). Thus, as shown in FIG. 20A, which will be explained later, low ceiling surfaces 44 (first ceiling surfaces) for preventing mixture of the process gases are provided at both sides of the separation gas nozzle 41 in the circumferential direction of the turntable 2, and high ceiling surfaces 45 (second ceiling surfaces) which are higher than the ceiling surfaces 44 are provided at further both sides of the ceiling surfaces 44 in the circumferential direction. The outer peripheral end portion of the protruding portion 4 (the outer peripheral end portion of the vacuum chamber 1) faces the outer end surface of the turntable 2 as well as being bent in an L-shape with a small space between the chamber body 12 in order to prevent missing of the process gases. FIG. 20A and FIG. 20B are cross-sectional views of the vacuum chamber 1 taken along a line extending in the circumferential direction of the turntable 2.

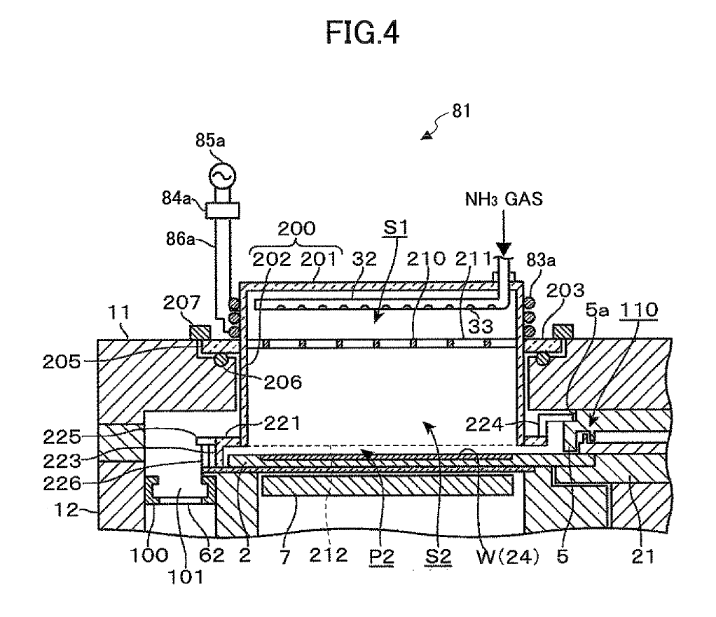

Next, a structure of a first plasma processing unit (the first plasma generation unit 81 and the plasma generation chamber 200) is explained in detail with reference to FIG. 4 to FIG. 11.

The second process gas nozzle 32 is housed inside the plasma generation chamber 200. In this embodiment, the second process gas nozzle 32 is positioned higher than the ceiling plate 11.

As shown in FIG. 1 to FIG. 7, the plasma generation chamber 200 has substantially a box shape, a lower surface side of which is opened, which extends in a band shape between a center portion side and an outer periphery portion side of the turntable 2 in a plan view. In other words, the plasma generation chamber 200 is a vertical flat container. The plasma generation chamber 200 is made of a material which is permeable to high frequency waves such as quartz, alumina or the like.

For the plasma generation chamber 200, an upper portion (hereinafter, referred to as an upper chamber 201 (an example of a first surrounding portion)) in which the second process gas nozzle 32 is housed is positioned higher than the ceiling plate 11. Further, the plasma generation chamber 200 is inserted from an upper side of the ceiling plate 11 into the vacuum chamber 1 in an air-tight manner so that a lower end opening portion at a lower portion (hereinafter, referred to as a lower chamber 202 (an example of a second surrounding portion)) thereof is positioned closer to the turntable 2. As shown in FIG. 4, the plasma generation chamber 200 is further provided with a flange portion 203 at its outer periphery surface between the upper chamber 201 and the lower chamber 202 which protrudes in a horizontal direction along the circumferential direction.

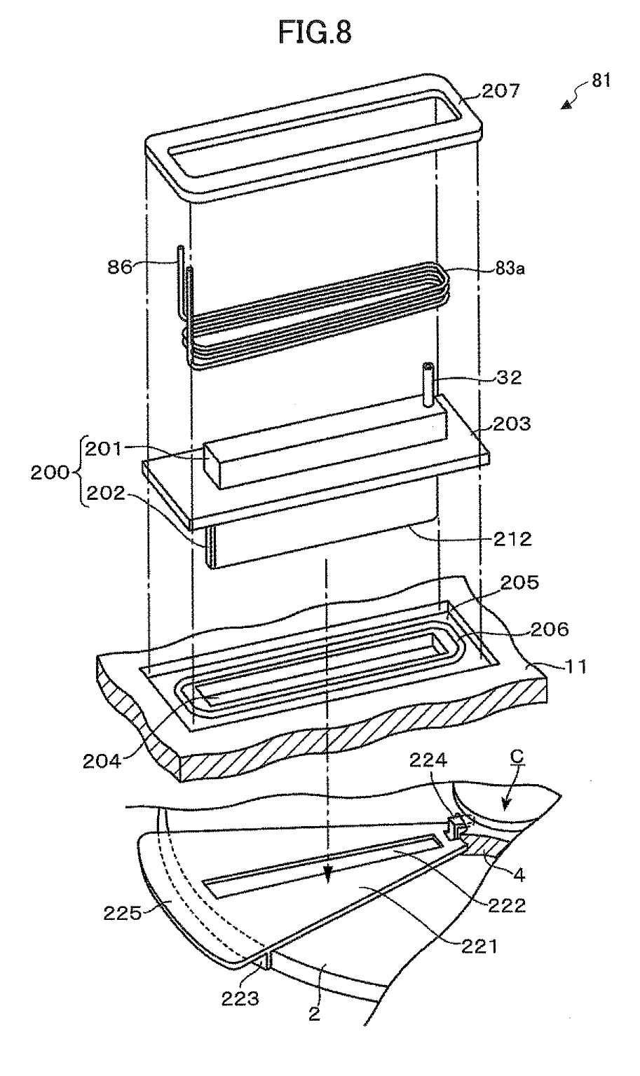

As shown in FIG. 8, the ceiling plate 11 is provided with an opening portion 204 in which the plasma generation chamber 200 is to be inserted and a step portion 205 formed around the upper surface to be slightly concaved with respect to the upper surface of the ceiling plate 11 to correspond to the flange portion 203, at the upper surface of the ceiling plate 11.

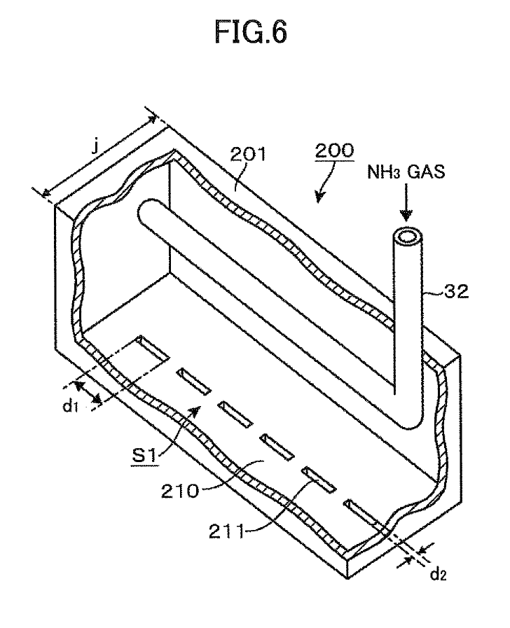

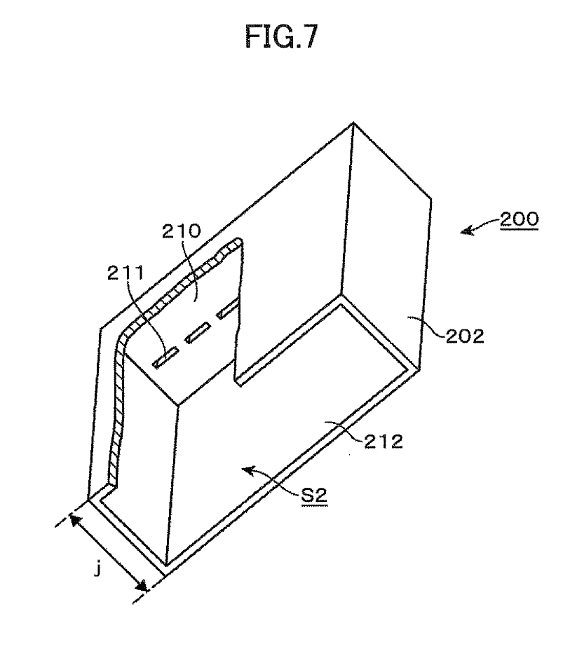

When inserting the plasma generation chamber 200 (a unit of the upper chamber 201 and the lower chamber 202) to the opening portion 204, the step portion 205 and the flange portion 203 engage with each other and the plasma generation chamber 200 contacts the vacuum chamber 1 in an air-tight manner by a sealing member 206 such as an O-ring or the like provided at the step portion 205 to surround the opening portion 204. Thus, as shown in FIG. 8, when the flange portion 203 is pushed toward the vacuum chamber 1 by a pushing member 207 which is formed in substantially a ring shape along the flange portion 203 and then the pushing member 207 is fixed to the vacuum chamber 1 by bolts or the like (not shown in the drawings), the inside area of the vacuum chamber 1 and the inside area of the plasma generation chamber 200 become in communication with each other in an air-tight manner. Here, FIG. 5 to FIG. 7 show a state where a part of the plasma generation chamber 200 is removed, FIG. 6 is a view showing the upper chamber 201 from an upper side, and FIG. 7 is a view showing the lower chamber 202 from a lower side.

The second process gas nozzle 32 is fixed to the upper chamber 201 by welding, for example. The second process gas nozzle 32 is inserted in the plasma generation chamber 200 (the upper chamber 201) from the upper surface of the plasma generation chamber 200 at a position close to the center portion of the turntable 2 and then is bent toward the outer periphery end portion of the turntable 2 to be extended along the longitudinal direction of the plasma generation chamber 200 in the horizontal direction. Further, a partition plate 210 is provided inside the plasma generation chamber 200 between the upper chamber 201 and the lower chamber 202 for regulating flow of gas (specifically, plasma) as well as preventing intrusion of the separation gas into the upper chamber 201.

As shown in FIG. 4 to FIG. 7, the partition plate 210 is provided with plural discharge ports 211 each of which has a slit shape extending in the radial direction of the turntable 2 along the second process gas nozzle 32 below the second process gas nozzle 32. By providing the partition plate 210 provided with the discharge ports 211, the pressure in the upper chamber 201 can be adjusted separately (independently) from that of the vacuum chamber 1, as shown in the examples in the following.

As shown in FIG. 6, the length “j” of the plasma generation chamber 200 in the circumferential direction of the turntable 2 is 30 to 60 mm, for example. The length “d1” of the discharge port 211 is about 10 mm to 60 mm, and the width “d2” of the discharge port 211 is about 2 mm to 8 mm. Further, as shown in FIG. 5, electrical damage to the wafers W are easy to occur if the distance “k” between the lower end surface of the second process gas nozzle 32 and the upper surface of the partition plate 210 is too small, while it becomes hard for plasma to reach the wafers W if the distance “k” is too large, as will be explained later. Thus, the distance “k” is about 30 to 100 mm, for example. Here, a distance between the wafer W on the turntable 2 and the lower end surface of the ceiling plate 11 is about 70 mm to 30 mm, for example (see FIG. 1 or FIG. 5).

As shown in FIG. 4, for example, the first plasma generation unit 81 is provided around the upper chamber 201 as an activating unit which performs a plasma activation of ammonia gas discharged from the second process gas nozzle 32.

The first plasma generation unit 81 includes a high frequency power source 85a, a matching transformer 84a, a connection electrode 86a, and an antenna 83a. The antenna 83a is made of a metal wire such as copper or the like. The, antenna 83a is wound around the upper chamber 201 in a coil shape around a vertical axis for three times, for example, in a plan view. The frequency of the high frequency power source 85a may be 13.56 MHz and the output power of the high frequency power source 85a may be 1000 W to 5000 W, for example. The antenna 83a is connected to the high frequency power source 85a via the connection electrode 86a and the matching transformer 84a.

The inside area of the upper chamber 201 is a plasma generation space S1. The first plasma generation unit 81, the plasma generation chamber 200 and the second process gas nozzle 32 compose the plasma processing unit.

In this embodiment, as shown in FIG. 7, the lower chamber 202 forms substantially a box shape area extending along the radial direction of the turntable 2 (a direction from the center portion side toward the outer periphery portion side of the turntable 2) from the ceiling plate 11 side toward the turntable 2 in the vacuum chamber 1 below the discharge ports 211 of the partition plate 210. The inside area of the lower chamber 202 becomes a guide space S2 for guiding the plasma discharged from the plasma generation space S1, which is the inside area of the upper chamber 201, via the discharge ports 211 toward the turntable 2. The lower chamber 202 is provided with a plasma discharge opening 212 at its lower end portion. The height “h” between the plasma discharge opening 212 and the wafer W on the turntable 2 (see FIG. 20A or FIG. 20B) is about 0.5 to 3 mm, for example.

The film deposition apparatus of the embodiment further includes a fin 221 which functions as a flow regulation plate (rectifier) formed to surround the plasma discharge opening 212 of the lower chamber 202 in a plate form along the turntable 2 (FIG. 1, FIG. 2 and FIG. 8 to FIG. 11). The fin 221 is provided for flowing the plasma discharged from the plasma discharge opening 212 toward the turntable 2 along the turntable 2, as well as suppressing the diffusion of the plasma by the separation gas.

As shown in FIG. 8, the fin 221 is composed of a plate member having substantially a sector top view shape which expands from the center portion side toward the outer periphery portion side of the turntable 2. The fin 221 is provided with an opening portion 222 which has substantially the same shape as the plasma discharge opening 212 of the lower chamber 202. The fin 221 includes a bended portion 223, a horizontal surface portion 225, support portions 226 (FIG. 10) and a support portion 224. The bended portion 223 is bended downward at an edge portion of the turntable 2 at the outer periphery portion side. The horizontal surface portion 225 further extends over the bended portion 223 at the outer periphery portion side of the turntable 2 to protrude toward an inner wall surface of the vacuum chamber 1. Each of the support portions 226 has substantially a columnar shape provided at a lower surface side of the horizontal surface portion 225 (see FIG. 10). The support portion 224 is provided at upper end portion near the rotational center of the turntable 2.

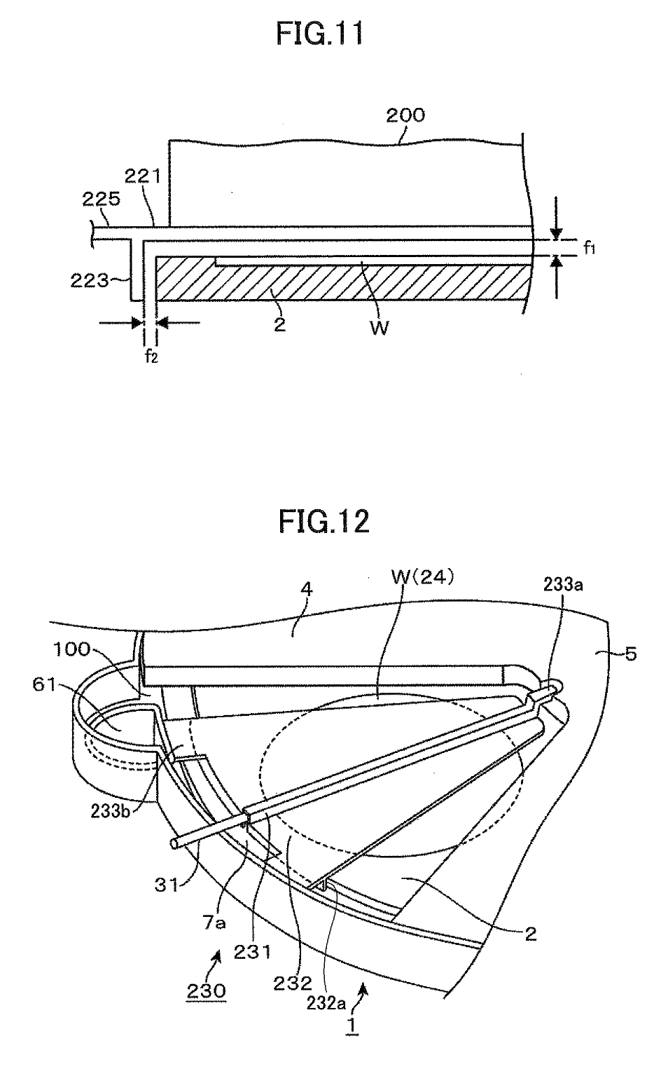

As shown in FIG. 11, the banded portion 223 is bent after being extended from the outer periphery end surface of the turntable 2 for about 5 to 30 mm, for example, such that a space is provided between the outer periphery end surface of the turntable 2. The distance “f1” between the upper surface of the turntable 2 and the fin 221 and the distance “f2” between the outer periphery end surface of the turntable 2 and the bended portion 223 are set to be as equivalent as the above explained distance “h”. In this embodiment, the lower surface of the fin 221 is positioned at a height substantially the same as the lower surface of the plasma generation chamber 200 (plasma discharge opening 212).

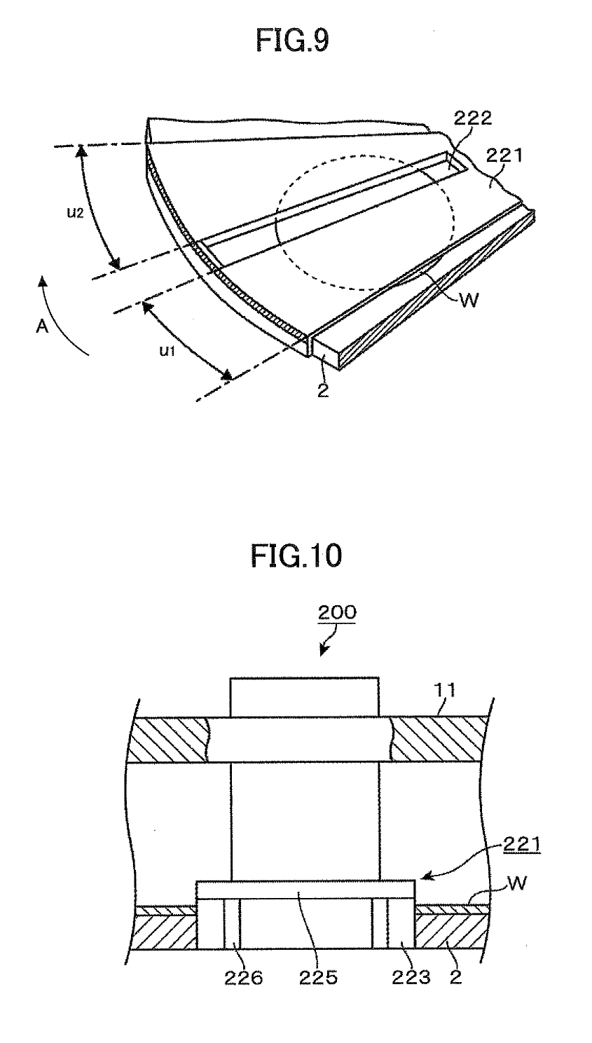

Further, as shown in FIG. 9, the width “u2” of the fin 221 in the circumferential direction of the turntable 2 at a downstream side of the plasma generation chamber 200 in the rotational direction A of the turntable 2 is formed to be longer than the width “u1” of the fin 221 in the circumferential direction of the turntable 2 at a upstream side of the plasma generation chamber 200 in the rotational direction A of the turntable 2, at the outer periphery end of the fin 221. The width “u1” is 80 mm, and the width “u2” is 200 mm, for example.

Here, FIG. 10 is a view showing the fin 221 seen from outer periphery end side of the turntable 2, and FIG. 11 is a view showing the fin 221 seen from the side.

The fin 221 is detachably attached to the vacuum chamber 1. The support portion 224 (see FIG. 8) is formed from an upper end portion at a rotational center side of the turntable 2 upward and is bent toward the center area C in a horizontal direction. The support portion 224 is configured to be supported by a notch portion 5a, which will be explained later, formed at the protruded portion 5. The support portion 226 is supported by the cover member 7a, which will be explained later, at the lower end surface.

With this structure, as shown in FIG. 8, when the plasma generation chamber 200 is moved downward through the ceiling plate 11 after the fin 221 is placed in the vacuum chamber 1, the lower end portion of the plasma generation chamber 200 is inserted in the opening portion 222 of the fin 221 with a space between the fin 221. In FIG. 8, a part of the protruding portion 4 is not shown, and in FIG. 9, the horizontal surface portion 225 and the support portion 226 are omitted.

By providing the fin 221 as structured above, as shown in the following examples, the ammonia gas plasma flows along the wafer W on the turntable 2 so that an area where the plasma and the wafer W contact is widely formed in the circumferential direction and in the radial direction of the turntable 2. In other words, the plasma below the plasma discharge opening 212 moves downstream in the rotational direction of the turntable 2 by evacuation of the evacuation port 62 may diffuse toward the outer periphery end portion of the turntable 2 (the inner wall surface of the vacuum chamber 1). However, as the fin 221 is provided closer to the turntable 2, the flow of the plasma below the fin 221 is regulated not to move toward the outer periphery end portion of the turntable 2 and the plasma below the fin 221 moves along the circumferential direction of the turntable 2.

Further, the plasma discharged from the plasma discharge opening 212 below the plasma discharge opening 212 may flow upstream in the rotational direction of the turntable 2. However, in this embodiment, as can be understood from the following examples, by providing the fin 221, the flow of the plasma toward upstream can be suppressed. The reason is as follows, for example.

The flow of the plasma toward the upstream side in the rotational direction of the turntable 2 is opposite to the rotational direction of the turntable 2. Thus, if the fin 221 is not provided, the plasma may be blown up by the rotation of the turntable 2. However, in this embodiment, as the fin 221 is provided, the plasma discharged from the plasma discharge opening 212 is suppressed not to be blown upward and the plasma flows along the turntable 2 by the fin 221. Thus, the speed of the flow of the plasma fin 221 becomes slower as moving toward the upstream side in the rotational direction of the turntable 2 by the rotation of the turntable 2. As a result, the plasma flows downstream of the rotational direction of the turntable 2. Thus, as a whole, by providing the fin 221, the plasma flows toward the downstream of the rotational direction of the turntable 2 in the circumferential direction of the turntable 2 without flowing toward the upstream side below the plasma discharge opening 212.

Further, as the fin 221 is provided to be closer to the turntable 2, the intrusion of the separation gas below the fin 221 from the upstream side and the downstream side can be suppressed. Specifically, as the distance “f1” (see FIG. 11) between the fin 221 and the turntable 2 is extremely small, the separation gas flows in a flowing space above the fin 221 without flowing in an area between the fin 221 and the turntable 2. Further, the fin 221 is provided with the bended portion 223 which blocks a space above the turntable 2 and the outer periphery side of the turntable 2. Thus, it is hard for the plasma below the fin 221 to flow toward the outer periphery side of the turntable 2. Therefore, the plasma below the fin 221 does not flow to the outer periphery side of the turntable 2 by the nitrogen gas supplied to the center area C and the concentration of the plasma in the radial direction of the turntable 2 becomes equal. With this structure, a wide area in which the ammonia gas plasma of a high concentration uniformly exists is formed below the fin 221 along the rotational direction of the turntable 2 as well as in the radial direction of the turntable 2.

Further, as explained above, the plasma generation chamber 200 is inserted from upward into the fin 221. Here, a space of about 1 mm, for example is formed between the plasma generation chamber 200 and the fin 221 in the circumferential direction in a plan view. Thus, the upper area and the lower area of the fin 221 are in communication with each other via the space. However, as the area of the high concentration ammonia plasma is formed below the fin 221 as described above, as can be understood from the following examples, the gas which flows above the fin 221 such as the nitrogen gas is prevented from flowing into the plasma generation chamber 200 via the space.

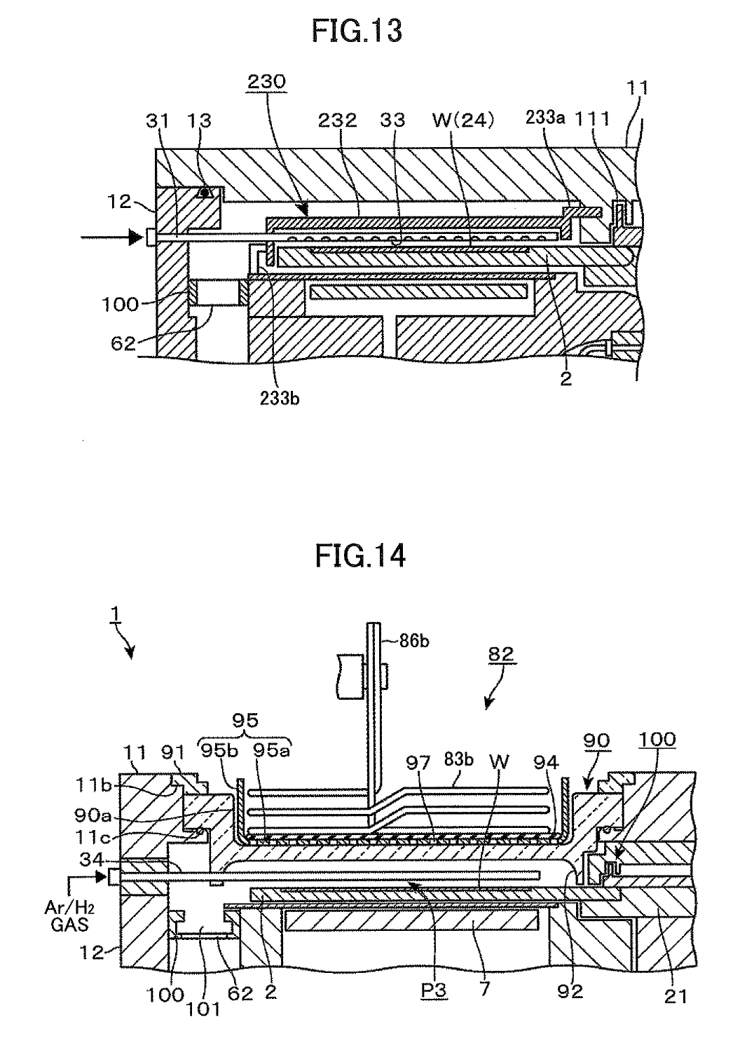

Subsequently, the first process gas nozzle 31 is explained with reference to FIG. 12 and FIG. 13.

A nozzle cover 230 similarly formed as the fin 221 is provided above the first process gas nozzle 31 for having the first process gas flowing along the wafer W as well as the separation gas flows in the ceiling plate 11 side of the vacuum chamber 1 preventing it from flowing near the wafer W. The nozzle cover 230 includes a cover body 231 having substantially a box shape with an opening at the lower side for housing the first process gas nozzle 31, and flow regulation plates 232 provided at both sides of the cover body 231 at the lower ends thereof at the upstream side and the downstream side in the rotational direction of the turntable 2. The sidewall of the cover body 231 near the rotation center side of the turntable 2 extends toward the turntable 2 to face the front end portion of the first process gas nozzle 31. Further, a part of the sidewall of the cover body 231 at the outer periphery end portion of the turntable 2 is removed in order not to interfere with the first process gas nozzle 31. The nozzle cover 230 is further provided with a bent portion 232a which is formed at a lower surface of the flow regulation plates 232 to extend downward between the outer periphery end of the turntable 2 and the inner wall surface of the vacuum chamber 1 for preventing intrusion of the separation gas supplied to the center area C into the area above the turntable 2 to dilute the first process gas supplied from the first process gas nozzle 31. The nozzle cover 230 is further provided with support portions 233a and 233b which are respectively provided at one end and the other end in the longitudinal direction of the first process gas nozzle 31 to be supported by the protruded portion 5 and the cover member 7a, which will be explained later.

Next, a structure of a second plasma processing unit (the second plasma generation unit 82 and the housing 90) is explained in detail with reference to FIG. 14 to FIG. 18.

The second plasma generation unit 82 is provided above the third process gas nozzle 34 for performing plasma activation of a surface treatment gas (the third process gas) discharged from the third process gas nozzle 34 into the vacuum chamber 1. Similar to the first plasma generation unit 81, the second plasma generation unit 82 includes a high frequency power source 85b, a matching transformer 84b, a connection electrode 86b and an antenna 83b. The antenna 83b is made of a metal wire and is formed into a coil shape by being wounded around the vertical axis for three times, for example. The antenna 83b is formed to surround a band shaped area extending in the radial direction of the turntable 2 in a plan view as well as passing through the diameter of the wafer W on the turntable 2. The antenna 83b is positioned lower than or at the same level as the ceiling plate 11. The frequency of the high frequency power source 85b may be 13.56 MHz and the output power of the high frequency power source 85b may be 5000 W, for example. The antenna 83b is connected to the high frequency power source 85b via the connection electrode 86b and the matching transformer 84b. The antenna 83b is provided to be separated from the inside area of the vacuum chamber 1.

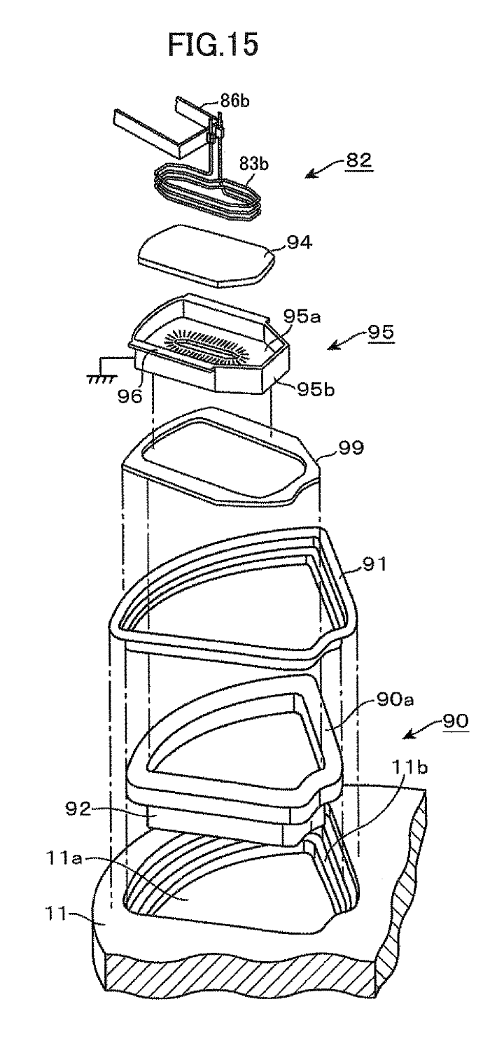

The third process gas nozzle 34 is provided lower than the ceiling plate 11. The ceiling plate 11 is provided with an opening portion 11a having substantially a sector top view shape (FIG. 15). A housing 90 made of a dielectric body such as quartz for example is provided in the opening portion 11a.

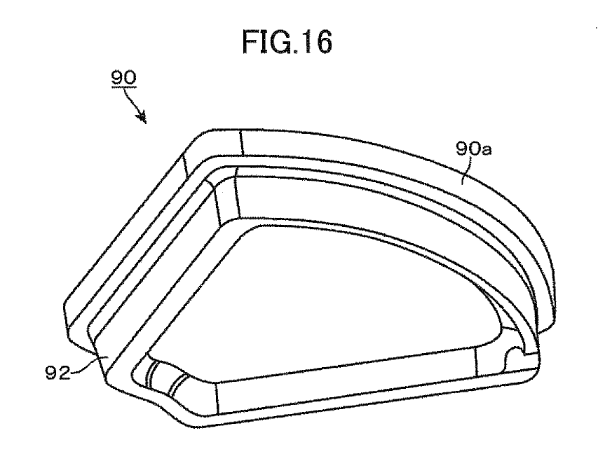

FIG. 16 is a view showing the housing 90 seen from a lower side. The housing 90 is provided with a flange portion 90a formed at an upper side where an outer peripheral end portion extends in a horizontal direction along the circumferential direction as a flange. Further, when seen in a plan view, a part of the housing 90 which positions at a center side portion of the vacuum chamber 1 is formed to concave toward inside area of the vacuum chamber 1. The housing 90 is positioned to cover the diameter of the wafer W in the radial direction of the turntable 2 when the wafer W is positioned below. There is provided a sealing member 11c (FIG. 14) such as an O-ring or the like between the housing 90 and the ceiling plate 11.

As shown in FIG. 15, by inserting the housing 90 into the opening portion lie of the ceiling plate 11, then pushing the flange portion 90a downward along the circumferential direction by a pushing member 91 which has a frame shape along the outer end of the opening portion 11a, and fixing the pushing member 91 to the ceiling plate 11 by a bolt or the like (not shown in the drawings), atmosphere inside the vacuum chamber 1 is kept air-tight.

As shown in FIG. 14, the housing 90 is provided with a protruding portion 92 which protrudes downward toward the turntable 2 to surround the third process areas P3 along the circumferential direction. The third process gas nozzle 34 is positioned in an area surrounded by the inner wall of the protruding portion 92, the lower surface of the housing 90 and the upper surface of the turntable 2. The protruding portion 92 is provided with a notch portion to receive the third process gas nozzle 34 at the base portion side of the third process gas nozzle (near the inner wall side of the vacuum chamber 1).

As shown in FIG. 14, when seeing the sealing member 11c which seals the ceiling plate 11 and the housing 90 from the lower side of the housing (from the third process areas P3), the protruding portion 92 is provided between the third process areas P3 and the sealing member 11c along the circumferential direction. Thus, the sealing member 11c is separated from the third process areas P3 not to be directly exposed to the plasma. Therefore, the plasma diffuses from the third process areas P3 toward the sealing member 11c needs to pass below the plasma protruding portion 92 so that the plasma is deactivated before reaching the sealing member 11c.

As shown in FIG. 15, there is provided a grounded Faraday shield 95 which is a conductive plate such as a metal plate made of copper or the like, for example, and is formed to have a structure substantially corresponding to the inner shape of the housing 90 at the upper side of the housing 90. The Faraday shield 95 has a horizontal surface 95a horizontally formed to correspond to the bottom surface of the housing 90, and a vertical surface 95b which extends upward from the outer periphery end of the horizontal surface 95a along the circumferential direction upper side. The Faraday shield 95 is formed substantially hexagonal in a plan view.

Further, the Faraday shield 95 is further provided with support portions 96 which extend in the horizontal direction formed at the upper end. Further, a frame body 99 is provided between the Faraday shield 95 and the housing 90 which supports the support portions 96 from downward as well as being supported by the flange portion 90a of the housing 90 at the center area C side and the outer periphery portion side of the turntable 2.

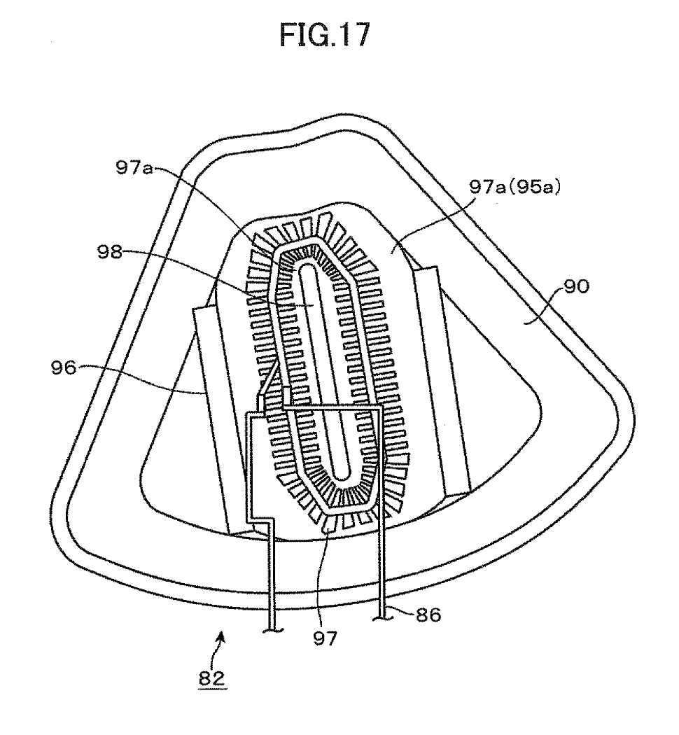

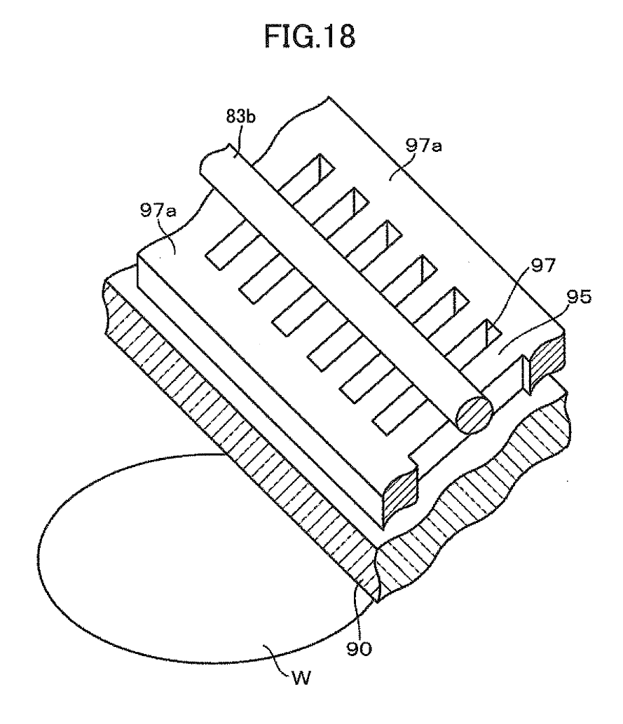

As shown in FIG. 17 and FIG. 18, the horizontal surface 95a of the Faraday shield 95 is provided with plural slits 97 for preventing the electric field component from passing downward while passing the magnetic field component to reach the wafer W, among the electromagnetic field component generated at the antenna 83b. If the electric field component reaches the wafer W, electric wiring formed inside the wafer W may be electrically damaged. Thus, the slits 97 are provided such that the electric field component is selectively shut while the magnetic field component is capable of passing therethrough as follows.

As shown in FIG. 17 and FIG. 18, specifically, the slits 97 are formed to extend in a direction perpendicular to the wound direction of the antenna 83 below the antenna 83 along the circumferential direction. Here, the wavelength corresponding to the high frequency supplied to the antenna 83 is 22 m, for example. Thus, each of the slits 97 is formed to have a width about 1/10000 or less of the wavelength. Further, the slits 97 are formed at a conductive path 97a made of a grounded conductive material. The Faraday shield 95 is further provided with an opening portion 98 for checking illuminating status of the plasma at a center corresponding to a center of the wound antenna 83. In FIG. 2, the slits 97 are not shown and only an area where the slits 97 are formed is drawn by a dotted line.

Referring back to FIG. 15, an insulating plate 94 made of quartz, for example, with a thickness about 2 mm is formed on a horizontal surface 95a of the Faraday shield 95 for insulating the Faraday shield 95 from the second plasma generation unit 82 mounted thereon. Thus, the second plasma generation unit 82 is placed to face inside (the wafer W on the turntable 2) of the vacuum chamber 1 via the housing 90, the Faraday shield 95 and the insulating plate 94.

Then, the components of the vacuum chamber 1 are explained again.

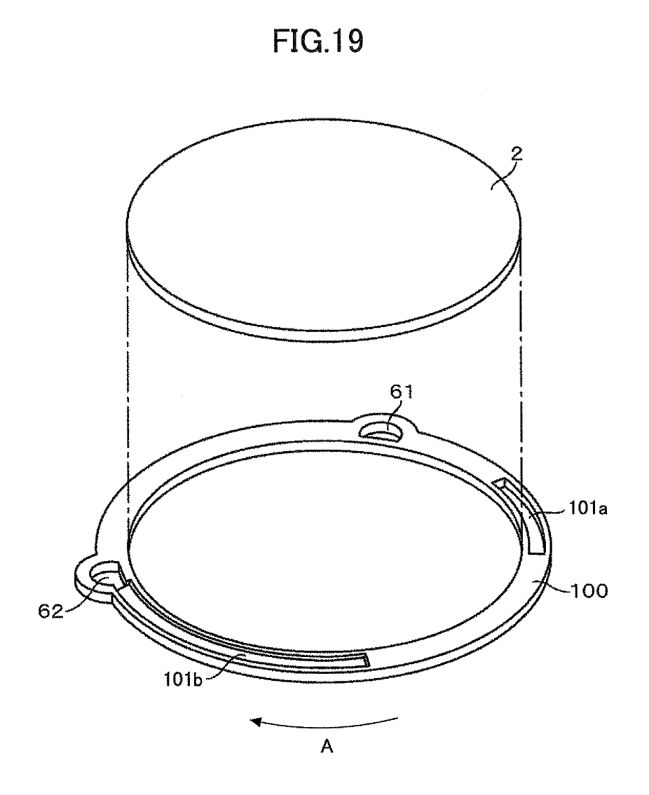

As shown in FIG. 19, there is provided a side ring 100, which is a cover body, around the outside periphery of the turntable 2 at slightly below the turntable 2. The side ring 100 is provided with a first evacuation port 61 and a second evacuation port 62 at two positions which are spaced apart from each other in the circumferential direction. In other words, the first evacuation port 61 and the second evacuation port 62 are formed in the side ring 100 at positions corresponding to evacuation ports formed at the bottom surface of the vacuum chamber 1. As shown in FIG. 2 or in FIG. 3, the first evacuation port 61 is positioned close to the second separation area D2 which is positioned at the downstream side of the first process gas nozzle 31 in the rotational direction of the turntable 2 between the first process gas nozzle 31 and the second separation area D2. The second evacuation port 62 is positioned close to the first separation area D1 which is positioned at the downstream side of the second plasma generation unit 82 in the rotational direction of the turntable 2 between the second plasma generation unit 82 and the first separation area D1. The first evacuation port 61 is purposed to evacuate the Si containing gas or the separation gas, while the second evacuation port 62 is purposed to evacuate the ammonia gas, the surface treatment gas or the separation gas. As shown in FIG. 1 (although only the second evacuation port 62 is exemplified), each of the first evacuation port 61 and the second evacuation port 62 is connected to a vacuum pump 64 which is a vacuum evacuation mechanism via an evacuation pipe 63 to which a pressure regulator 65 such as a butterfly valve is provided.

As described above, as the housing 90 and the plasma generation chamber 200 are provided along the center area C side toward the outer periphery side, respectively, the gases flowing toward the second process areas P2 and the third process areas P3 from the upstream side in the rotational direction of the turntable 2 are prevented from flowing toward the first evacuation port 61 and the second evacuation port 62 by the housing 90 and the plasma generation chamber 200. Thus, as shown in FIG. 19, there are provided a gas passage 101a and a gas passage 101b each being in a groove shape at the upper surface at the outer periphery side which is outside of the housing 90 and the plasma generation chamber 200 for flowing the gases. Specifically, as shown in FIG. 19, the gas passage 101a is formed in an arc shape from a position about 60 mm from an end portion of the plasma generation chamber 200 at the upstream side in the rotational direction of the turntable 2, close to the first evacuation port 61, to a position about 240 mm from an end portion of the plasma generation chamber 200 at the downstream side in the rotational direction of the turntable 2, close to the transfer port 15, with a depth about 30 mm, for example. Further, the gas passage 101b is also formed in an arc shape from a position about 120 mm from an end portion of the formed housing 90 at the upstream side in the rotational direction of the turntable 2, close to the transfer port 15, to the evacuation port 62 with a depth about 30 mm, for example.

As shown in FIG. 1 and FIG. 3, there is provided a protruded portion 5 at a center position at the lower surface of the ceiling plate 11. The protruded portion 5 is formed in substantially a ring shape along the circumferential direction to be continued from a portion of the protruding portion 4 at the center area C. Further, the lower surface of the protruded portion 5 is formed to have a height substantially the same as the lower surface (the ceiling surface 44) of the protruding portion 4. With reference to FIG. 1, there is provided a labyrinth structure portion 110 at further center side than the protruded portion 5 in the turntable 2 at the upper side of the core unit 21, for preventing mixture of the Si containing gas, the ammonia gas or the like in the center area C. As can be understood from FIG. 1, as the plasma generation chamber 200 and the housing 90 are provided at positions closer to the center area C side, the core unit 21 which supports the center portion of the turntable 2 is selectively formed at the center portion in order not to intervene the housing 90 and the like. Thus, the process gases may be easily mixed at the center area C side compared with a case in the outer periphery portion side. However, by providing the labyrinth structure portion 110, mixing of the gases can be prevented.

Specifically, as shown in FIG. 1, the labyrinth structure portion 110 includes a first wall portion 111 which vertically extends from the turntable 2 side toward the ceiling plate 11 side, and a the turntable 2 which vertically extends from the ceiling plate 11 side toward the turntable 2 along the circumferential direction, respectively, so that the wall portions 111 and 112 are alternately positioned in the radial direction of the turntable 2. In this embodiment, the second wall portion 112, the first wall portion 111 and the second wall portion 112 (where the second wall portions 112 are a part of the protruded portion 5) are positioned in this order from the protruded portion 5 side toward the center area C side.

Thus, in the labyrinth structure portion 110, the Si containing gas discharged from the first process gas nozzle 31 and directed to the center area C, for example, needs to pass through the first wall portion 111 and the second wall portion 112. Thus, the speed of the Si containing gas becomes slower toward the center area C and it is hard for the Si containing gas to be diffused. Therefore, the Si containing gas is pushed back toward the first process areas P1 by the separation gas supplied to the center area C before reaching the center area C. Further, similarly, the ammonia gas, the argon gas or the like which move toward the center area C are blocked by the labyrinth structure portion 110. Thus, mixing of the process gases in the center area C can be prevented.

On the other hand, the nitrogen gas supplied from upper side toward the center area C tends to rapidly spread in the circumferential direction, as the labyrinth structure portion 110 is provided, the speed of the nitrogen gas becomes slow as the nitrogen gas passes through the first wall portion 111 and the second wall portion 112 in the labyrinth structure portion 110. At this time, the nitrogen gas would enter into the extremely narrow area between the turntable 2 and the fin 221 or the protruding portion 92, for example, however, as the speed of the nitrogen gas is slowed by the labyrinth structure portion 110, the nitrogen gas flows toward the area wider than the narrow area (the area where the transfer arm 10 is introduced, for example). Thus the nitrogen gas is prevented from flowing into the plasma discharge opening 212 or the lower side of the housing 90.

As shown FIG. 1, there is provided a heater unit 7 in a space between the turntable 2 and the bottom portion 14 of the vacuum chamber 1 so that the wafer W on the turntable 2 is heated to 300° C., for example, through the turntable 2.

The vacuum chamber 1 further includes a cover member 7a which covers a protruded portion 71a provided at a side of the heater unit 7 and the upper side of the heater unit 7. Further, the bottom portion 14 of the vacuum chamber 1 is provided with purge gas supplying pipes 73 formed in the circumferential direction for purging the space where the heater unit 7 is provided below the heater unit 7.

As shown in FIG. 2 and FIG. 3, a transfer port 15 is provided at a sidewall of the vacuum chamber 1 for passing the wafers W between an external transfer arm 10 and the turntable 2. The transfer port 15 is capable of being opened and closed by a gate valve G in an air-tight manner. Further, a camera unit 10a for detecting an outer periphery edge portion of the wafer W is provided above the ceiling plate 11 where the transfer arm 10 moves closer to and far from the vacuum chamber 1. In other words, the camera unit 10a is for detecting whether the wafer W is mounted on the transfer arm 10, whether the wafer W is mounted on the turntable 2, or a misalignment of the wafer W mounted on the turntable 2, for example, by imaging the outer peripheral end portion of the wafer W. Thus, the camera unit 10a is provided to have a large field view for the area between the plasma generation chamber 200 and the housing 90 with a width corresponding to the diameter of the wafer W.

As the wafer W is passed between the transfer arm 10 and the concave portions 24 of the turntable 2 when the concave portions 24 faces the transfer port 15, there is provided lift pins for passing through the respective concave portion 24 to lift up the wafer W from the backside surface and a lifting mechanism for the lift pins (neither are shown in the drawings) below the turntable 2 at the position corresponding to the transfer port 15.

As shown in FIG. 1, the film deposition apparatus of the embodiment includes a control unit 120 composed of a computer and a storing unit 121. The control unit 120 controls the entirety of the film deposition apparatus. The control unit 120 includes a memory storing a program for performing the film deposition process and the surface treatment process, which will be explained later. The program is formed to include steps capable of executing the operation of the film deposition apparatus and is installed from the storing unit 121 which is a recording medium such as a hard disk, a compact disk (CD), a magneto-optic disk, a memory card, a flexible disk, or the like.

The operation of the embodiment is explained.

First, the gate valve G is opened, and five, for example, wafers W are mounted on the turntable 2 by the transfer arm 10 through the transfer port 15 while intermittently rotating the turntable 2. It is assumed that an interconnect structure formed by dry etching, Chemical Vapor Deposition (CVD) or the like is previously formed in each of the wafers W. Then, the gate valve G is closed, and the vacuum chamber 1 is evacuated to ultimate pressure by the vacuum pump 64 and the pressure regulator 65. Subsequently, the wafers W are heated to, for example, 300° C. by the heater unit 7 while rotating the turntable 2 in the clockwise direction.

Subsequently, the Si containing gas is supplied from the first process gas nozzle 31 at 300 sccm, for example, as well as the ammonia gas is supplied from the second process gas nozzle 32 at 100 sccm, for example. Further, the mixed gas of the argon gas and the hydrogen is supplied from the third process gas nozzle 34 at 10000 sccm, for example. Further, the separation gas is supplied from the separation gas nozzles 41 and 42 at 5000 sccm, respectively, for example, while the nitrogen gas is supplied from the separation gas supplying pipe 51 and the purge gas supplying pipes 72 and 73 at a predetermined flow rate. Then, the vacuum chamber 1 is set to be a predetermined set process pressure, 400 to 500 Pa, for example, by the pressure regulator 65. In this example, the predetermined pressure is 500 Pa. Further, at the first plasma generation unit 81 and the second plasma generation unit 82, the high frequency powers of 1500 W, for example, are supplied to the antennas 83a and 83b, respectively.

In the plasma generation chamber 200, when the ammonia gas is supplied from the second process gas nozzle 32 into the upper chamber 201, the ammonia gas is plasma activated by the electric field component and the magnetic field component generated by the antenna 83a. Then, the generated plasma may move toward the lower chamber 202. Here, as the partition plate 210 is provided between the upper chamber 201 and the lower chamber 202, the gas flow of the plasma is regulated by the partition plate 210. Thus, the pressure in the upper chamber 201 becomes a slightly higher than the other area in the vacuum chamber 1 so that the high pressure plasma moves downward toward the wafer W through the discharge ports 211 provided in the partition plate 210. At this time, as the pressure of the upper chamber 201 is kept higher than the other area in the vacuum chamber 1, other gases such as the nitrogen gas do not enter the upper chamber 201. Further, the plasma discharged from the plasma discharge opening 212 of the lower chamber 202 moves along the wafer W toward the downstream side in the rotational direction of the turntable 2 at the respective radius of the turntable 2 by the function of the fin 221, as explained above.

Here, as described above, in the plasma generated inside the upper chamber 201 includes a mixture of active species of the argon gas plasma and the ammonia gas plasma (NH radical) activated by the argon gas plasma, for example. Among the active species included in the plasma, for example, the argon ion which tends to cause ion damage to the wafer W has a shorter lifetime compared with the active species which does not tend to cause such ion damage to the wafer W, the ammonia gas plasma or the like, for example. The active species which do not tend to cause the ion damage have a longer lifetime than the argon gas plasma or the like, for example, to be kept activated even moving downward in the plasma generation chamber 200. Thus, the proportion of the active species which do not cause the ion damage to the wafer W, the ammonia gas plasma, becomes increased while moving downward in the plasma generation chamber 200.

In the housing 90, the electric field component among the electric field component and the magnetic field component generated by the antenna 83b is reflected or adsorbed (attenuated) by the Faraday shield 95 so is prevented from reaching into the vacuum chamber 1. Further, as the conductive paths 97a are provided at both ends in the lateral direction of each of the slits 97, and the vertical surface 95b is provided at the side of the antenna 83b, the electric field component can be shut between both ends of each of the slits 97. On the other hand, as the slits 97 are provided in the Faraday shield 95, the magnetic field component passes through the slits 97 to be introduced into vacuum chamber 1 through the bottom surface of the housing 90. With this, the surface treatment gas is plasma activated by the magnetic field component below the housing 90. Thus, the argon gas plasma is composed of active species which do not easily cause an electrical damage to the wafer W.

At this time, as the argon gas plasma has a lifetime shorter than that of the ammonia gas plasma, the argon gas plasma may soon be deactivated and become original argon gas. However, in the second plasma generation unit 82, as the antenna 83 is provided near the wafer W on the turntable 2, in other words, the area where the plasma is generated is provided right above the wafer W, the argon gas plasma can be directed to the wafer W while being kept activated. Then, as shown in FIG. 14, as the protruding portion 92 is provided at the lower surface of the housing 90 in the circumferential direction, the gas or the plasma below the housing 90 does not move outside the housing 90. Therefore, the pressure in the atmosphere below the housing 90 becomes slightly higher than the other area (the area where the transfer arm 10 is introduced, for example) in the vacuum chamber 1. Thus, the gas is prevented from being introduced into the housing 90.

At this time, the Si containing gas is adsorbed onto the surface of the wafer W at the first process areas P1, the Si containing gas adsorbed on the surface of the wafer W is nitrided by the ammonia gas plasma at the second process areas P2 so that the reaction product of a thin film, which is one or more molecular layers of silicon nitride (SiN), is formed, by the rotation of the turntable 2. At this time, impurities such as chlorine (Cl), an organic compound or the like may be included in the silicon nitride film due to the residual component included in the Si containing gas, for example.

Then, when the plasma from the second plasma generation unit 82 contacts the surface of the wafer W by the rotation of the turntable 2, the surface treatment of the silicon nitride film is performed. Specifically, for example, when the plasma collides the surface of the wafer W, the impurities are discharged from the silicon nitride film as HCl, organic gases or the like, or the elements in the silicon nitride film are rearranged to be dense (to have high density) the silicon nitride film, for example. By continuing the rotation of the turntable 2, adsorption of the Si containing gas onto the surface of the wafer W, nitriding of the Si containing gas adsorbed on the surface of the wafer W and the surface treatment of the reaction product by the plasma are performed for plural times in this order so that the reaction products are stacked to form the thin film. Here, as described above, although the interconnect structure is formed in the wafer W, as there is a large distance between the area where the plasma is generated and the wafer W in the first plasma generation unit 81 the electrical damage to the interconnect structure can be suppressed. Further, the electric field component is shut in the second plasma generation unit 82 so that the electrical damage to the interconnect structure can be suppressed.

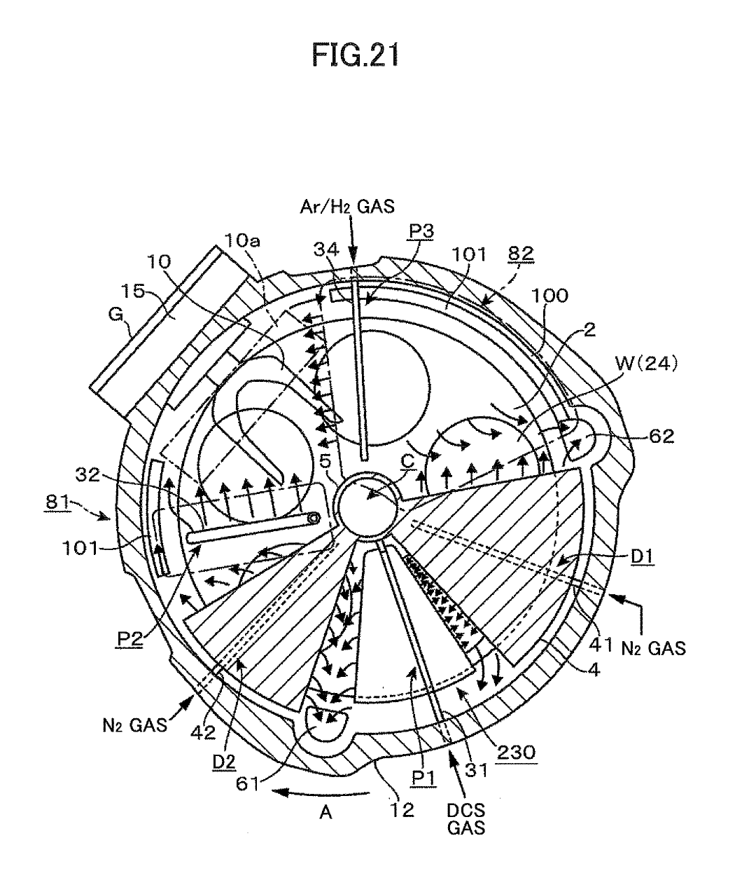

Then, as shown in FIG. 20B and FIG. 21, as the second separation area D2 and the first separation area D1 are respectively provided between the first process areas P1 and the second process areas P2 in the circumferential direction of the turntable 2, the gases are evacuated toward the first evacuation port 61 and the second evacuation port 62 while mixing of the Si containing gas and the ammonia gas is prevented in the second separation area D2 and the first separation area D1, respectively.

According to the embodiment, the upper chamber 201 as a plasma processing unit for forming a plasma generation space S1 in order to perform a plasma nitriding process to the wafer W is provided at higher than the ceiling plate 11 as well as providing the lower chamber 202 for guiding the plasma to the wafer W on the turntable 2 below the upper chamber 201. Thus, the areas and the members such as the antenna 83a, the second process gas nozzle 32 and the like necessary for the plasma process can be provided above and far from the turntable 2. Thus, the area necessary for the second process areas P2 in a plan view can be reduced (the area for the second process areas P2 in the circumferential direction of the turntable 2) so that the vacuum chamber 1 can be made smaller in a plan view.

Further, as the upper chamber 201 and the lower chamber 202 are integrally formed as the plasma generation chamber 200, as well as the upper chamber 201 is provided at a higher position than the ceiling plate 11, it is not necessary to provide an area for disposing the antenna 83a and the second process gas nozzle 32 in the vacuum chamber 1. In other words, as various components such as the gas nozzles 31, 34, 41 and 42, the protruding portions 4 and the like are provided in the vacuum chamber 1, there is not plenty of space for the second process gas nozzle 32 and the plasma generation space S1. On the other hand, there is plenty of space above the ceiling plate 11 of the vacuum chamber 1 compared with inside the vacuum chamber 1 and it is easier to provide the second process gas nozzle 32 or the plasma generation space S1. Thus, even for a small apparatus (the vacuum chamber 1), a space for transferring the wafer W and a space for providing the camera unit 10a can be retained.

Further, in this embodiment, for the gas which is to be plasma activated in the plasma generation space S1 is the ammonia gas which can react with the Si containing gas adsorbed on the wafer W. As described above, the ammonia gas plasma has a lifetime longer than that of the argon gas plasma or the like (capable of being plasma activated for longer period). Thus, although the plasma generation space S1 is provided at a position higher than the ceiling plate 11 and the distance between the plasma generation space S1 and the wafer W is made larger in this embodiment, the plasma process can be appropriately performed on the wafer W.

Further, as the partition plate 210 with the discharge ports 211 is provided in the plasma generation chamber 200, the pressure in the upper chamber 201 can be made higher than the other area (the area where the transfer arm 10 is introduced, for example) in the vacuum chamber 1. Thus, the pressure in the upper chamber 201 can be set independently from the vacuum chamber 1, and the pressure of the upper chamber 201 can be adjusted in accordance with the process recipe or the kinds of the wafer W, for example. Specifically, when a hole or groove with a high aspect ratio (deeper depth) is formed at the surface of the wafer W, the pressure of the upper chamber 201 may be set 200 Pa higher, for example, than that of the other area in order to have the coverage of the reaction product formed on the wafer W high. Further, as the nitrogen gas is not introduced into the upper chamber 201, adverse effects by the plasma activated nitrogen gas can be prevented.

Further, the fin 221 is provided to be closer to the wafer W on the turntable 2 at both sides of the plasma generation chamber 200 (the lower chamber 202) in the circumferential direction of the turntable 2 and the outer periphery end portion of the fin 221 is bent downward. Thus, contacting period for the ammonia gas plasma and the wafer W can be made longer.

Further, the plasma generation chamber 200 is formed to have a vertical longitudinal axis with a flat width shape, in other words, the plasma generation chamber 200 is formed in a band shape extending along the radial direction of the turntable 2. Thus, the length “j” (see FIG. 7) of the plasma generation chamber 200 in the circumferential direction of the turntable 2 can be made extremely shorter.

Further, as the plasma generation space S1 (the upper chamber 201) is provided to have a large distance from the wafer W, it is not necessary to provide a Faraday shield, which is similar to the Faraday shield 95 provided for the second plasma generation unit 82, for the first plasma generation unit 81. Thus, for the first plasma generation unit 81, the high frequency power source 85a with a small output power of low cost compared with a case when the Faraday shield 95 is provided may be used. In other words, if the Faraday shield 95 is provided, the electric power consumed as the electric field component, among the output power by the high frequency power source 85, is lost by the Faraday shield 95. However, if the Faraday shield 95 is not provided, the electric field component also contributes to the plasma activation for the ammonia gas plasma. Thus, by providing the upper chamber 201 at a position higher than the ceiling plate 11, the first plasma generation unit 81 can be simplified and cost can be lowered by the lower output power.

At this time, as the Faraday shield 95 is provided between the second plasma generation unit 82 and the wafer W, the electric field component generated in the second plasma generation unit 82 can be shut. Thus, the electrical damage by plasma to the interconnect structure in the wafer W can also be prevented in the second plasma generation unit 82. Further, as two plasma generation units, the first plasma generation unit 81 and the second plasma generation unit 82, are provided, different kinds of plasma processes can be combined. Therefore, different kinds of plasma processes such as the plasma nitriding process for the Si containing gas adsorbed on the surface of the wafer W and the plasma surface treatment process of the reaction product, as described above can be combined to increase a flexibility of the apparatus.

Further, as the antenna 83a and the antenna 83b are provided outside the vacuum chamber 1 for the first plasma generation unit 81 and the second plasma generation unit 82, respectively, maintenance of the first plasma generation unit 81 and the second plasma generation unit 82 becomes easier.

Subsequently, another example of the film deposition apparatus is explained.

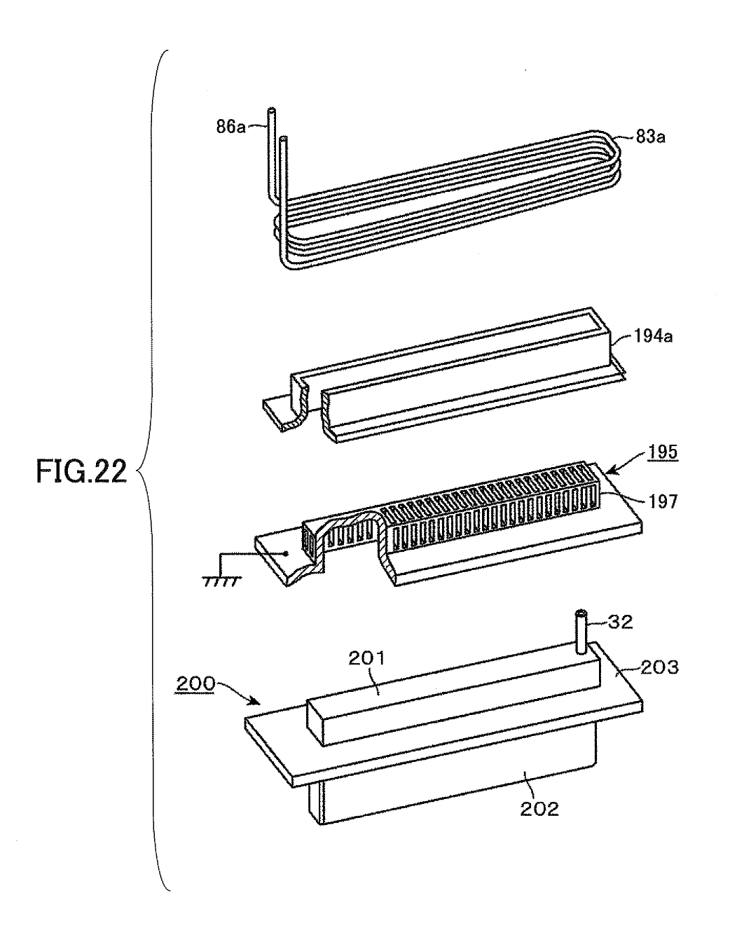

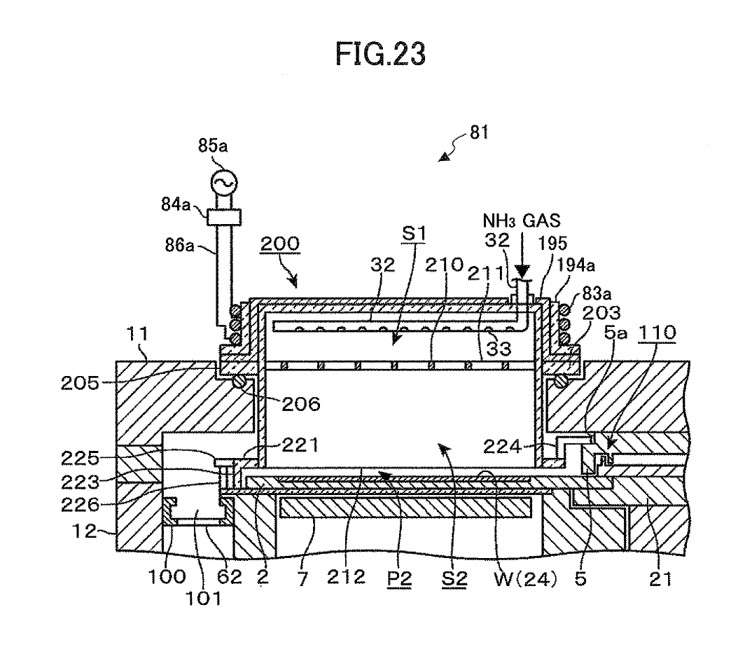

FIG. 22 and FIG. 23 are views showing an example where a Faraday shield 195 is provided for the first plasma generation unit 81, similar to the second plasma generation unit 82. Specifically, the Faraday shield 195 has a structure having substantially a box shape to house the upper chamber 201 provided with an opening at the lower side and a flange portion extending outside in the circumferential direction provided around the opening. The Faraday shield 195 is provided with plural slits 197 each extending in a direction perpendicular to the winding direction of the antenna 83a. In other words, the slits 197 are formed to extend in the vertical direction at the side surfaces of the Faraday shield 195. Further, each of the slits 197 formed at the upper surface of the Faraday shield 195 extends in the circumferential direction of the turntable 2.

Further, there is provided an insulating member 194a between the Faraday shield 195 and the antenna 83a to insulate the Faraday shield 195 and the antenna 83a. The insulating member 194a is formed to have a rectangular tube form which surrounds the Faraday shield 195 in the circumferential direction. In FIG. 22, a part of the Faraday shield 195 and a part of the insulating member 194a are not shown.

When this kind of the first plasma generation unit 81 is used, even when the high output power is supplied to the antenna 83a from the high frequency power source 85a, the electrical damage to the wafer W can be suppressed.

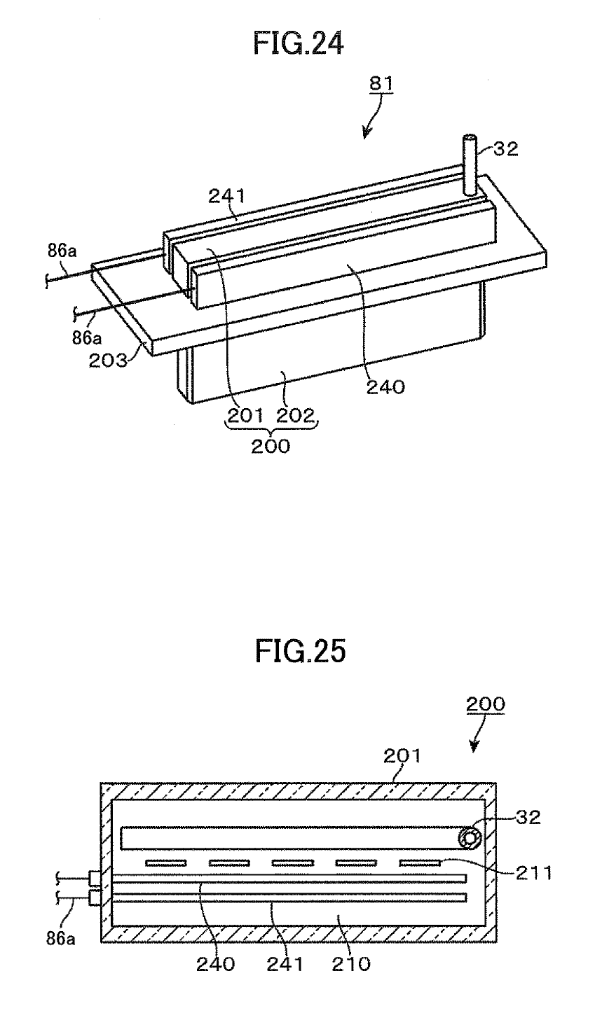

FIG. 24 is a view showing an example in which a Capacitively Coupled Plasma (CCP) is used for the first plasma generation unit 81 instead of the Inductively Coupled Plasma (ICP) in which the antenna 83a is wound around the plasma generation chamber 200. There are plate electrodes 240 and 241 each extending in the radius direction of the turntable 2 at one side and the other side of the upper chamber 201 in the circumferential direction of the turntable 2, respectively. The electrodes 240 and 241 are connected to the matching transformer 84a and the high frequency power source 85a.

With this structure, the ammonia gas is plasma activated in the upper chamber 201 by the high frequency power supplied to the electrodes 240 and 241. With CCP, as the upper chamber 201 is provided far from the wafer W, the ion damage to the wafer W can be suppressed.

Further, FIG. 25 is a view in which the electrodes 240 and 241 shown in FIG. 24 are formed in a stick shape, respectively, and disposed in the upper chamber 201 along the second process gas nozzle 32. At this time, the electrodes 240 and 241 are covered by a coating material such as quartz or the like having a plasma resistance characteristic.

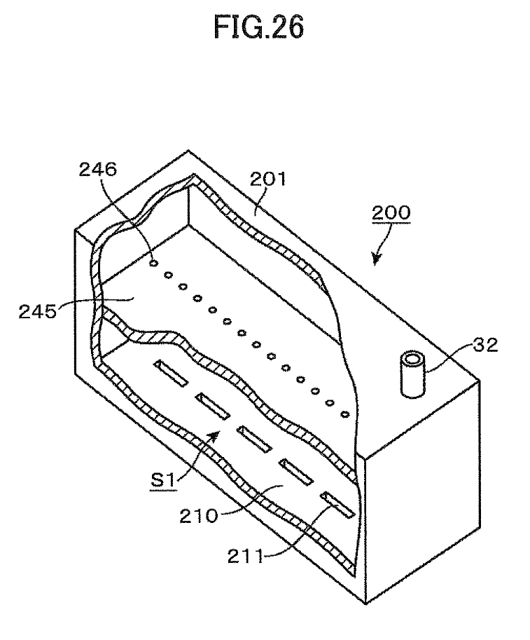

FIG. 26 is a view showing an example where an additional partition plate 245 is further disposed between the ceiling surface of the upper chamber 201 and the partition plate 210 for further petitioning the inside area of the upper chamber 201 in a horizontal direction instead of disposing the second process gas nozzle 32 in the upper chamber 201. The additional partition plate 245 is provided with plural gas discharge holes 246 along the radial direction of the turntable 2. The front end portion of the second process gas nozzle 32 is fixed as the upper end surface of the upper chamber 201.

The ammonia gas supplied from the second process gas nozzle 32 spreads above the additional partition plate 245 along the longitudinal direction of the upper chamber 201 in the upper chamber 201 and is supplied to the wafer W via the gas discharge holes 246 and the discharge ports 211. At this time, any of the ICP plasma source and CCP plasma source may be used.

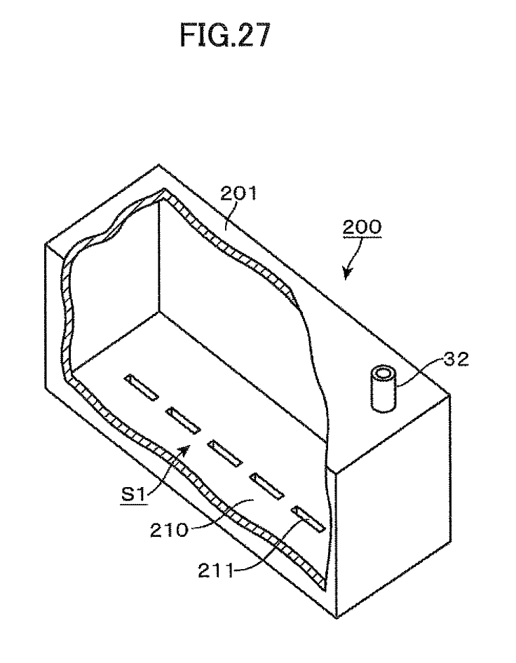

Further, FIG. 27 is a view in which the additional partition plate 245 shown in FIG. 26 is not disposed and the ammonia gas supplied into the upper chamber 201 directly flows downward toward the discharge ports 211.

Further, although the fin 221 is provided below the plasma generation chamber 200 in the above described examples, the fin 221 may not be provided.

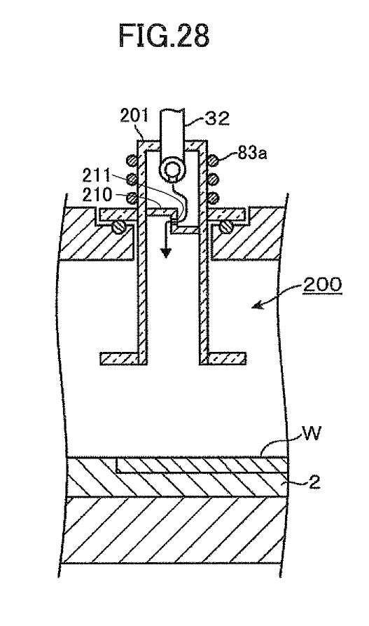

Further, although each of the discharge ports 211 is formed to penetrate the partition plate 210 in the vertical direction, the discharge ports 211 may be formed to penetrate the partition plate 210 in the lateral direction. For this case, as shown in FIG. 28, the partition plate 210 may be formed to have a part extending in the vertical direction where the discharge ports 211 are to be formed, between two horizontal parts. At this time, the discharge ports 211 are formed at the lower part of the upper chamber 201.

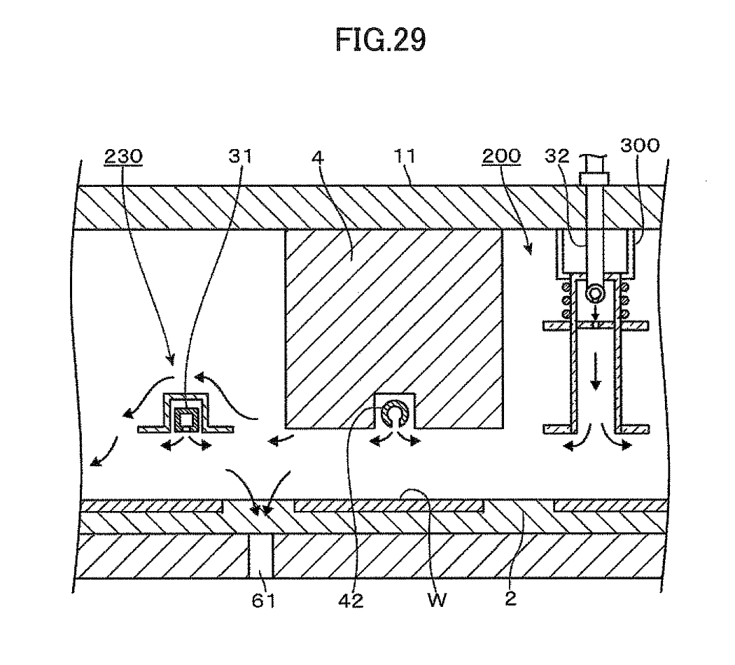

Further, although the upper chamber 201 is formed at a position higher than the ceiling plate 11 in order to make the area necessary for plasma activating the ammonia gas smaller in a plan view in the above described examples, the upper chamber 201 may be provided in the vacuum chamber 1. As shown in FIG. 29, for example, the upper chamber 201 may be provided in the vacuum chamber 1 for the case when the ceiling plate 11 is provided to have a large distance from the turntable 2 and the upper chamber 201 does not interfere the first process area P1, the third process area P3, the first separation area D1, and the second separation area D2 even when the upper chamber 201 is housed in the vacuum chamber 1. Even for this case, the area of the second process area P2 in the circumferential direction can be reduced in a plan view, and the vacuum chamber 1 can be made smaller. At this time, for example, the plasma generation chamber 200 may be hung by the ceiling plate 11 via a hanging member 300.

Further, for the second plasma generation unit 82, the CCP type plasma source may be used in which the electrodes 240 and 241 are inserted from the sidewall of the vacuum chamber 1 in an air-tight manner along the third process gas nozzle 34 as shown in FIG. 25 instead of providing the antenna 83b and the housing 90. Further, one of the first plasma generation units 81 as explained above may be used as the second plasma generation unit 82.

Further, Bis Tertiary-Butylamino Silane (BTBAS: SiH₂(NHC(CH₃)₃)₂)) gas may be used as the first process gas instead of the DCS gas, and oxygen (O₂) gas may be used as the second process gas instead of the ammonia gas, for example. At this time, the oxygen gas is plasma activated in the first plasma generation unit 81 and silicon oxide film (SiO) is formed as the reaction product.

Further, when forming the silicon oxide film, an ozonizer (not shown in the drawings) for generating active species of oxygen gas (ozone) from the oxygen gas may be provided outside the vacuum chamber 1 instead of the first plasma generation unit 81 and the active species may be provided from the ozonizer into the vacuum chamber. When the ozonizer is used, the plasma generation chamber 200 is used instead of the housing 90 for performing the plasma surface treatment process of the reaction product.

Further, although in the above embodiment, the plasma surface treatment process is performed every time a layer of the reaction product is formed by the rotation of the turntable 2, the plasma surface treatment process may be performed every time plural layers of the reaction product are formed. Specifically, first, plural layers of the reaction product are formed by rotating the turntable 2 plural times, under a condition in which power supply from the high frequency power source 85b to the antenna 83b or the electrodes 240 and 241 for plasma activating the surface treatment gas is terminated. Then, supplying of the first process gas and the second process gas is terminated, and the plasma surface treatment process is performed on the layers of the reaction product by supplying the power supply from the high frequency power source 85b while rotating the turntable 2. The thin film is formed by alternately repeating forming of the layers of the reaction product and the plasma surface treatment process. For the case when the plasma surface treatment process is performed for the plural layers, the third process area P3 may be provided between the first process area P1 and the second process area P2 in the rotational direction of the turntable 2.

Further, for the surface treatment gas used for the surface treatment process for the reaction product in the second plasma generation unit 82, helium (He) gas or nitrogen gas may be used instead of or in addition to the mixed gas of the argon gas and the hydrogen gas.

### EXAMPLE

### Example 1

The simulation performed in the film deposition apparatus as explained above with reference to FIG. 1 in accordance with the following conditions is explained.

In this simulation, the pressure of the vacuum chamber 1, the flow rate of the ammonia gas, whether the fin 221 is provided and the width d2 of each of the discharge ports 211 of the partition plate 210 are varied as parameters. Then, the pressure distribution, path lines of flow gases and mass concentration distributions of flow gases (nitrogen gas, argon gas, ammonia gas and DCS gas) in the vacuum chamber 1 are examined. The pressure distribution, the path lines and the mass concentration distributions at a position 1 mm above from the surface of the turntable 2 are measured.

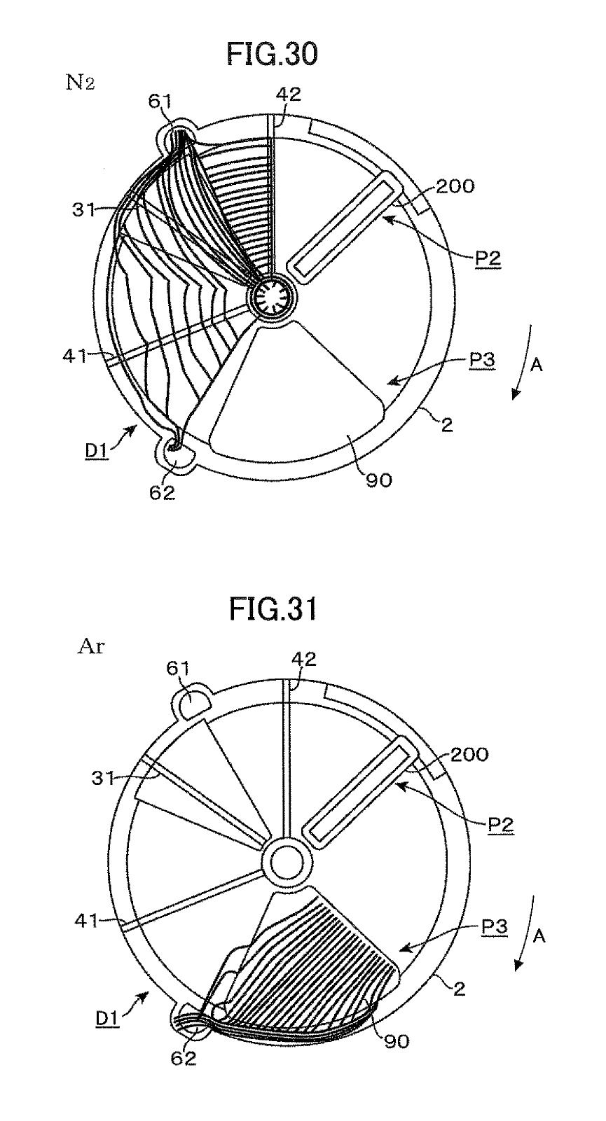

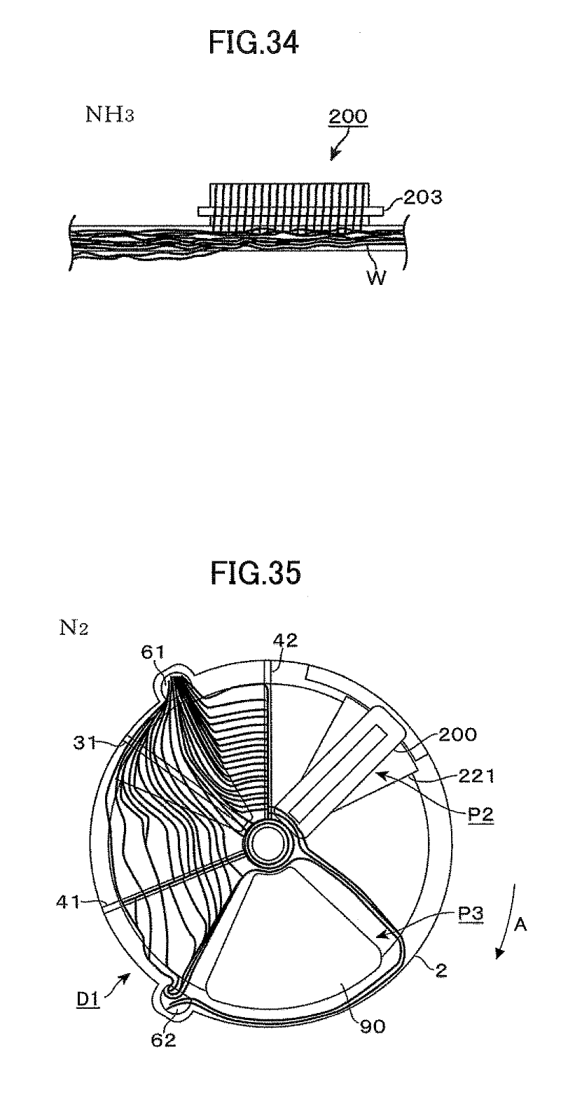

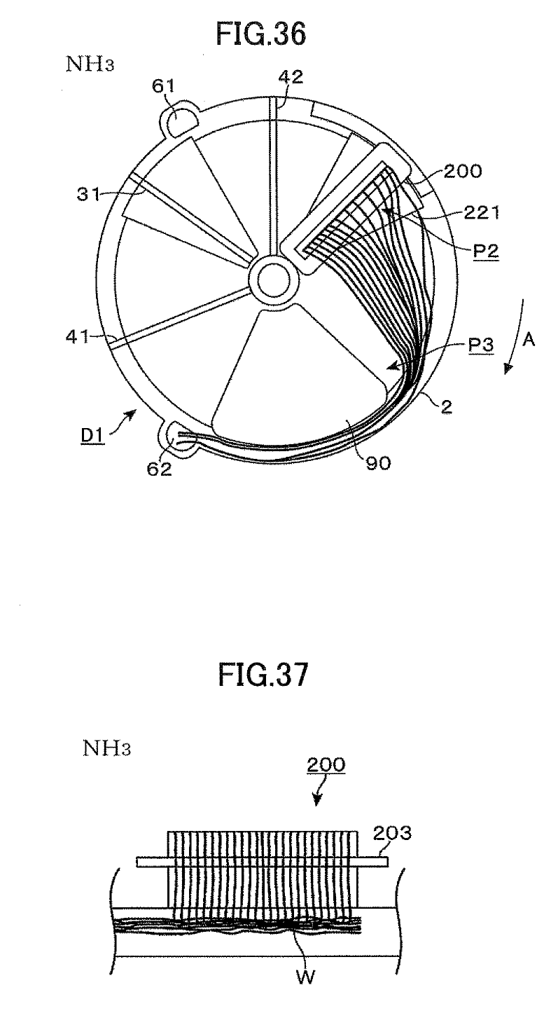

FIG. 30 to FIG. 33, FIG. 35 and FIG. 36 are plan view of the vacuum chamber 1 and FIG. 34 and FIG. 37 to FIG. 39 are cross-sectional views of the plasma generation chamber 200 taken along a line extending in the radial direction of the turntable 2. Further, although the ammonia gas is plasma activated in the vacuum chamber 1, the plasma ammonia gas is simply referred to as “ammonia gas”.

TABLE 1
(Simulation condition)

| | PRESSURE | | | |
|---|---|---|---|---|
| | IN VACUM | AMMONIA | | |
| | CHAMBER | GAS | | d2 |
| | (Pa(Torr)) | (slm) | FIN | (mm) |
| EXAMPLE 1-1 | 266.6 (2) | 5 | × | 5 |
| EXAMPLE 1-2 | | | ◯ | |
| EXAMPLE 1-3 | 133.3 (1) | | × | |
| EXAMPLE 1-4 | | 2 | | |
| EXAMPLE 1-5 | | 5 | ◯ | |
| EXAMPLE 1-6 | | | | 2 |

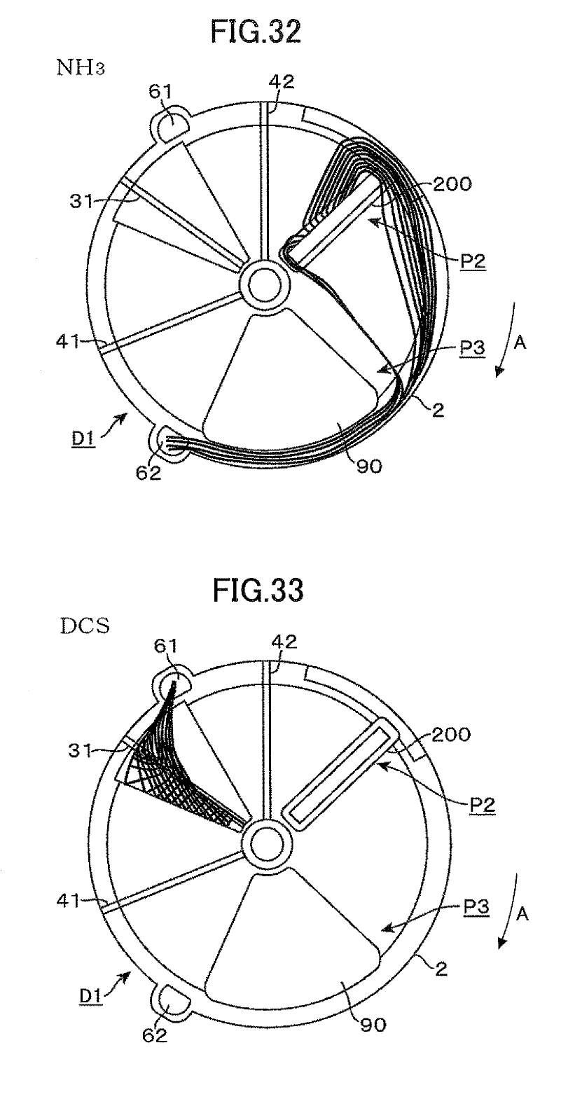

In example 1-1 (FIG. 30 to FIG. 34), the fin 221 is not provided. Although not shown in the drawings, it is confirmed that the pressure becomes higher than the other area in the vicinity of each of the gas nozzles 31, 34, 41 and 42 in the vacuum chamber 1. FIG. 30 to FIG. 34 show path lines of gases in example 1-1. As can be understood from these drawings, the ammonia gas (FIG. 32) and the DOS gas (FIG. 33) are prevented from being mixed with each other by the nitrogen gas (FIG. 30). The same result is confirmed by the mass concentration distributions, though not shown in the drawings.

As shown in FIG. 34, the ammonia gas flows downward along the longitudinal direction of the plasma generation chamber 200 in the plasma generation chamber 200. At this time, as the fin 221 is not provided, as shown in FIG. 32, the ammonia gas flows at the upstream side in addition to the downstream side of the plasma generation chamber 200 in the rotation direction of the turntable 2. Further, as the argon gas (FIG. 31) widely spreads below the housing 90, the other gases are prevented from being introduced into the housing 90.

In example 1-2 (FIG. 35 to FIG. 37), the fin 221 is provided. Although not shown in the drawings, by providing the fin 221, compared with example 1-1 in which the fin 221 is not provided, the pressure of the vacuum chamber 1 below the plasma generation chamber 200 becomes higher.

FIG. 35 to FIG. 37 show path lines of gases in example 1-2. As shown in FIG. 36, compared with FIG. 32, the ammonia gas flowing toward the upstream side of the plasma generation chamber 200 in the rotational direction of the turntable 2 is prevented when the fin 221 is provided. Further, the ammonia gas spreads along the radial direction of the turntable 2 at the downstream side of the plasma generation chamber 200 in the rotational direction of the turntable 2 so that the ammonia gas spreads along the vicinity of the wafer W. Further, based on the mass concentration distribution of the ammonia gas, it is confirmed that the ammonia gas, a slight amount though, flows above the fin 211. It means that the pressure below the fin 211 becomes higher than that at above the fin 211. Thus, it is considered that the ammonia gas widely spreads below the fin 211 along the radius direction of the turntable 2. Further, even when the fin 221 is provided, the nitrogen gas appropriately separates the process gases (FIG. 35).

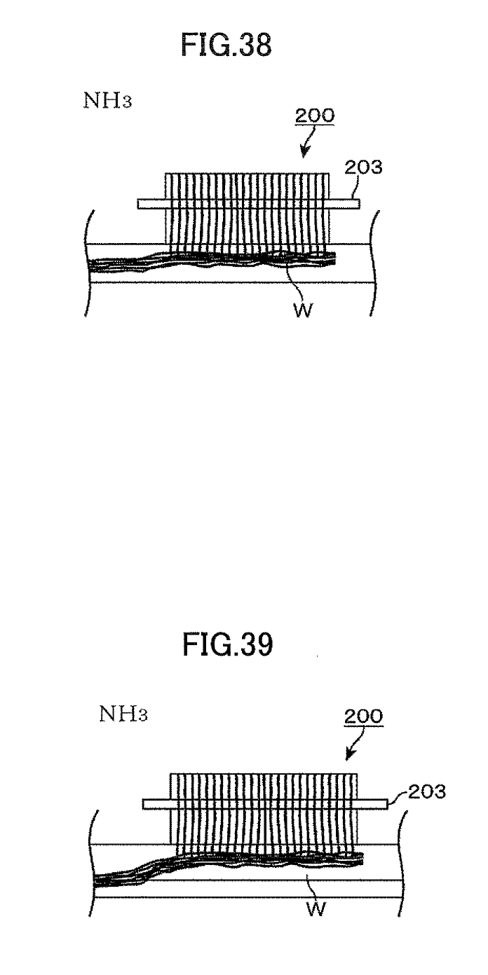

In examples 1-5 (FIG. 38) and 1-6 (FIG. 39), the width d2 of the discharge port 211 is varied. FIG. 38 and FIG. 39 show flow lines of example 1-5 and example 1-6, respectively. As a result, there is no change in the pressure of the vacuum chamber 1, the mass concentration distributions of the nitrogen gas and the ammonia gas. The ammonia gas distribution in the upper chamber 201 and in the lower chamber 202 of the plasma generation chamber 200 will be explained in the following example 2 (example 2-2, 2-7).

In example 1-3, the pressure of the vacuum chamber 1 is varied from that of example 1-1. However, as a result, the tendency of the pressure in the vacuum chamber 1 becomes substantially the same.

Subsequently, in example 1-4, the flow rate of the ammonia gas is changed from that of example 1-3. As a result, by reducing the flow rate of the ammonia gas (example 1-4), the pressure of the vacuum chamber 1 becomes lower substantially along the circumferential direction. Further, based on the mass concentration distributions of the nitrogen gas and the ammonia gas of example 1-4, the area where the ammonia gas spreads remains although the area becomes smaller.

### Example 2

Subsequently, parameters are changed as shown in table 2. The distribution of the ammonia gas in the vertical direction is examined.

TABLE 2
(Simulation condition)

| | PRESSURE | | | |
|---|---|---|---|---|
| | IN VACUM | AMMONIA | | |
| | CHAMBER | GAS | | d2 |
| | (Pa(Torr)) | (slm) | FIN | (mm) |
| EXAMPLE 2-1 | 133.3 (1) | 5 | × | 5 |
| EXAMPLE 2-2 | | | ◯ | |
| EXAMPLE 2-3 | 266.6 (2) | | × | |
| EXAMPLE 2-4 | | | ◯ | |
| EXAMPLE 2-5 | 133.3 (1) | 2 | × | |
| EXAMPLE 2-6 | | | ◯ | |
| EXAMPLE 2-7 | | 5 | | 2 |
| EXAMPLE 2-8 | | 2 | | |

By providing the partition plate 210 in the plasma generation chamber 200, it is confirmed that the pressure in the upper chamber 201 becomes slightly higher than that in the lower chamber 202. At this time, the pressures in the upper chamber 201 and the lower chamber 202 do not largely change based on the fin 221 (comparison of examples 2-1 and 2-2). Further, when the pressure of the vacuum chamber 1 is changed, for example, made higher (examples 2-3 and 2-4), or when the flow rate of the ammonia gas is changed, for example, made smaller (examples 2-5 and 2-6), the same results are obtained.

On the other hand, from examples 2-2 and 2-7 or examples 2-6 and 2-8, when the width d2 of the discharge port 211 is made narrower, the pressure of the upper chamber 201 becomes extremely higher than that of the lower chamber 202. At this time, when the flow rate of the ammonia gas becomes larger (example 2-8), the difference in pressure in the upper chamber 201 and the lower chamber 202 further becomes larger. Thus, for the plasma generation chamber 200, by adjusting the width d2 of the discharge port 211, and further adjusting the flow rate of the ammonia gas, an appropriate pressure for the plasma in accordance with the process recipe or the kind of the wafer W can be generated.

Although a preferred embodiment of the film deposition apparatus has been specifically illustrated and described, it is to be understood that minor modifications may be made therein without departing from the spirit and scope of the invention as defined by the claims.

According to the embodiment, when forming a thin film by alternately supplying plural kinds of process gases which react with each other onto the surface of the substrate in the vacuum chamber, the separation areas are provided between the process areas to which the process gases are supplied, respectively. Then, in the plasma processing unit, a first surrounding portion for a plasma generation space and a second surrounding portion below the first surrounding portion for guiding plasma to the substrate on the turntable are provided for performing a plasma process onto the substrate. Thus, the area or components necessary for the plasma process such as a plasma generation space, an activating unit or the like can be provided high above and far from the substrate on the turntable. Thus, the area for such the plasma generation space, the activating unit or the like can be made small to structure a small size vacuum chamber in a plan view.

The present invention is not limited to the specifically disclosed embodiments, and variations and modifications may be made without departing from the scope of the present invention.

What is claimed is:

1. A film deposition apparatus in which a thin film is formed on a substrate by performing a cycle for plural times in which plural kinds of process gases which react with each other are supplied onto the substrate so that a reaction product is stacked on the substrate in a vacuum chamber, comprising:
a turntable placed in the vacuum chamber and provided with a substrate mounting area on which a substrate is to be mounted at a surface for rotating the substrate mounting area;
a first process gas supplying unit which supplies a first process gas to a first process area;
a first plasma processing unit which performs a plasma process to the substrate at a second process area;
a separation gas supplying unit which supplies a separation gas to a separation area between the first process area and the second process area for separating atmospheres of the first process area and the second process area;
an evacuation port which evacuates the atmosphere of the vacuum chamber;
wherein the first plasma processing unit includes
a first surrounding portion for forming a plasma generation space where plasma is generated, provided with a discharge port at a lower end portion,
a second process gas supplying unit which supplies a second process gas to a plasma generation space,
an activating unit which activates the second process gas in the plasma generation space, and
a second surrounding portion provided below the first surrounding portion for forming a guide space which extends from a center portion side to an outer periphery portion side of the turntable so that the plasma discharged from the discharge port is guided to the surface of the turntable.

2. The film deposition apparatus according to claim 1,
wherein the vacuum chamber is provided with an opening portion at a ceiling portion,
a unit of the first surrounding portion and the second surrounding portion is inserted into the vacuum chamber via the opening portion, where the first surrounding portion is positioned higher than the ceiling portion.

3. The film deposition apparatus according to claim 1,
wherein the second process gas supplying unit is provided to be apart from the first process gas supplying unit in the circumferential direction of the turntable, and
the second process gas supplied from the second process gas supplying unit includes a gas which reacts with the first process gas adsorbed on the substrate.

4. The film deposition apparatus according to claim 1,
wherein the first plasma processing unit further includes a partition plate provided between the first surrounding portion and the second surrounding portion, and
the discharge port is composed of a slit provided in the partition plate.

5. The film deposition apparatus according to claim 4,
wherein the slit is provided to extend from the center portion side to the outer periphery portion side of the turntable.

6. The film deposition apparatus according to claim 1, further comprising:
a flow regulation plate which regulates a distance of a space above the substrate which is mounted on the turntable below the second surrounding portion and is provided along the longitudinal direction of the second surrounding portion at both sides of the lower portion of the second surrounding portion in the circumferential direction of the turntable.

7. The film deposition apparatus according to claim 6,
wherein the flow regulation plate further includes a bended portion bent downward to face the outer periphery end surface of the turntable with a space partitioning the lower area of the second surrounding portion and the outer periphery of the turntable.

8. The film deposition apparatus according to claim 1,
wherein the first surrounding portion is composed of the upper portion of a vertical flat box and the second surrounding portion is composed of the lower portion of the box.

9. The film deposition apparatus according to claim 1,
wherein the activating unit is an antenna provided to be wound around the first surrounding portion.

10. The film deposition apparatus according to claim 9,
wherein the first plasma processing unit includes a grounded Faraday shield composed of a conductive plate provided with plural slits extending in a first direction, which is perpendicular to a second direction, in which the antenna extends, disposed in the second direction and provided between the antenna and the first surrounding portion for preventing passing of the electric field component as well as allowing passing of the magnetic field component among the electromagnetic field components generated around the antenna toward the substrate.

11. The film deposition apparatus according to claim 1, further comprising:
a second plasma processing unit provided to be apart from the first plasma processing unit in the circumferential direction of the turntable for performing a plasma surface treatment process on the reaction product on the substrate at a surface treatment area,
the second plasma processing unit including
a third process gas supplying unit for supplying a third process gas to the surface treatment area,
a second antenna to plasma activate the second plasma generation gas, and
a grounded Faraday shield composed of a conductive plate provided with plural slits extending in a third direction, which is perpendicular to a fourth direction, in which the second antenna extends, disposed in the fourth direction and provided between the second antenna and the surface treatment area for preventing passing of the electric field component as well as allowing passing of the magnetic field component among the electromagnetic field components generated around the second antenna toward the substrate.

12. The film deposition apparatus according to claim 1,
wherein the second process gas supplying unit is positioned higher than the first process gas supplying unit.

13. The film deposition apparatus according to claim 12,
wherein the second process gas supplied by the second process gas supplying unit to the plasma generation space includes ammonia gas.
